(19) United States
(12) Patent Application Publication
(10) Pub. No.: US 2002/0058199 A1
(43) Pub. Date: May 16, 2002

(54) Novel polymers and photoresist compositions comprising electronegative groups

(75) Inventors: Anthony Zampini, Westborough, MA (US); Charles R. Szmanda, Westborough, MA (US); Sungseo Cho, Milford, MA (US); Gary N. Taylor, Northboro, MA (US)

Correspondence Address: Peter F. Corless, EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 09/948,903

(22) Filed: Sep. 8, 2001

Related U.S. Application Data
(60) Provisional application No. 60/231,274, filed on Sep. 8, 2000.
(60) Provisional application No. 60/253,118, filed on Nov. 27, 2000.

(51) Int. Cl. G03F 7/038; G03F 7/039; G03F 7/09; G03F 7/26

(52) U.S. Cl. 430/270.1; 430/325; 430/326; 430/272.1

(57) ABSTRACT

The present invention includes polymers and photoresist compositions that comprise the polymers as a resin binder component. Photoresists of the invention include chemically-amplified positive-acting resists that can be effectively imaged at short wavelengths such as sub-200 nm, particularly 157 nm. Particular polymers and photoresists of the invention include at least one electronegative group that reduces 157 nm absorbance of a wide spectrum of organic groups including aromatic groups such as phenolic moieties.

This application claims the benefit of U.S. provisional application No. 60/231,274 filed Sep. 8, 2000, and U.S. provisional application number 60/253,118, filed Nov. 27, 2000, both incorporated herein by reference.

### BACKGROUND OF THE INVENTION

1. Field of the Invention

The present invention relates to new polymers comprising electronegative groups and use of such polymers as a resin binder component for photoresist compositions, particularly chemically-amplified positive-acting resists that can be effectively imaged at short wavelengths such as sub-200 nm and preferably about 157 nm.

2. Background

Photoresists are photosensitive films used for transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist-coated substrate. Following exposure, the photoresist is developed to provide a relief image that permits selective processing of a substrate.

A photoresist can be either positive-acting or negative-acting. For most negative-acting photoresists, those coating layer portions that are exposed to activating radiation polymerize or crosslink in a reaction between a photoactive compound and polymerizable reagents of the photoresist composition. Consequently, the exposed coating portions are rendered less soluble in a developer solution than unexposed portions. For a positive-acting photoresist, exposed portions are rendered more soluble in a developer solution while areas not exposed remain comparatively less developer soluble. Photoresist compositions are described in Deforest, Photoresist Materials and Processes, McGraw Hill Book Company, New York, ch. 2, 1975 and by Moreau, Semiconductor Lithography, Principles, Practices and Materials, Plenum Press, New York, ch. 2 and 4.

While currently available photoresists are suitable for many applications, current resists also can exhibit significant shortcomings, particularly in high performance applications such as formation of highly resolved sub-half micron and sub-quarter micron features.

Consequently, interest has increased in photoresists that can be photoimaged with short wavelength radiation, including exposure radiation of about 250 nm or less, or even about 200 nm or less, such as wavelengths of about 193 nm. Use of such short exposure wavelengths can enable formation of smaller features. Accordingly, a photoresist that yields well-resolved images upon 248 nm or 193 nm exposure could enable formation of extremely small (e.g. sub-0.25 μm) features that respond to constant industry demands for smaller dimension circuit patterns, e.g. to provide greater circuit density and enhanced device performance.

### SUMMARY OF THE INVENTION

We have now found novel polymers and photoresist compositions that comprise the polymers as a resin binder component. The photoresist compositions of the invention can provide highly resolved relief images upon exposure to extremely short wavelengths, particularly sub-200 nm wavelengths, and even sub-170 nm or sub-160 nm wavelengths such as 193 nm and 157 nm. The polymers of the invention also are useful for resists imaged at higher wavelengths such as sub-300 nm e.g. 248 nm.

Polymers of the invention include aromatic groups, such as phenyl, phenol, naphthylene, etc., and one or more electron-withdrawing groups, such as a halogen, nitro, cyano, sulfinyl, sulfonyl, and the like. Halogen, particularly fluoro, are especially preferred groups.

We have surprisingly found that resins with an aromatic component and such electronegative substitution can exhibit good transparency at extremely short wavelengths such as 157 nm. See, for instance, the results set forth in the examples which follow. Without being bound to theory, preferred electronegative according to the invention attract electrons from a variety of polymer or co-polymer bonds to facilitate a reduction or avoidance of light absorbance in the sub-200 nm range, preferably at 157 nm.

Significantly, the present invention now permits use of photoresists in the sub-200 nm range that include polymers with aromatic ring substituents. Previously, such polymers has been avoided due to unwanted light absorbance below 200 nm and particularly 157 nm. However, we have now found that many aromatic ring substituents and especially phenolic rings and derivatives thereof provide photoresists useful for short wavelength imaging, such as sub-170 nm, particularly 157 nm.

Aromatic polymers of the invention may comprise a wide range of aromatic units. Preferred polymers include those that contain phenyl units, particularly hydroxy-substituted phenyl units. More particularly, novolaks and poly(vinylphenol) polymers are particularly preferred. The electronegative substitution is preferably a halogen particularly fluorine or a haloalkyl such as trifluoromethyl and the like. An electronegative substituent may be present e.g. as an aromatic ring substituent, as a substituent of a linkage between polymer repeat units, and/or as a substituent of a non-aromatic unit of the polymer.

Particularly preferred polymers for use in the resists of the invention include halogenated novolaks and halogenated polymers that comprise phenolic (such as provided by polymerization of vinylphenol) and/or other optionally substituted styrene units. Preferably the polymers are fluorinated. These aromatic polymers may suitably be halogenated particularly fluorinated at available positions of the aromatic ring as well as at methylene bridge units (of novolak polymers) and/or at available carbons of the polymer backbone (e.g. in the case of vinylphenol polymer where the polymer has pendant aromatic groups).

In a preferred aspect, the invention provides polymers and chemically amplified photoresists that contain distinct functional elements. These elements can be combined by one or a combination of different means. In a particular embodiment, these elements are illustrated by the following Formula I:

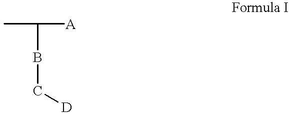

In that Formula I, the polymer backbone, A, is connected to a ballast moiety, B, which is usually present to give etch resistance and, optionally, to enhance other properties such as adhesion, and further connected to an acidic moiety, C, which, when not protected by a chemically cleavable group, D, is capable of promoting the dissolution of the polymer in aqueous base. D is typically only present in chemically amplified positive resists and is cleaved by acidolysis or hydrolysis in the imagwise exposed regions by a photogenerated strong acid.

Polymers in chemically amplified negative resists, usually do not contain element D. In negative resists, a crosslinking agent is present which, in the imagwise-exposed regions, connects two or more polymer chains, usually through the acidic moiety, C.

There have been problems using many prior photoresists at sub-200 nm wavelengths. Resist absorbance at 157 nm has been a particular concern. For example, most current resists require a film thickness of at least about 100 nm to provide acceptable etch performance particularly when plasma etchants are used. At that thickness or greater however, transmittance of sub-200 nm wavelengths such as 157 nm is often too low for good resolution imaging. The invention addresses these problems by providing photoresists with acceptable 157 nm light absorbance even when provided as a film having at least about 50-100 nm thickness.

More specifically, the invention provides novel polymers including at least one suitable electronegative group and photoresists comprising same that are capable of producing high-resolution images at less than 200 nm and especially 157 nm. Such photoresists can be configured in film form having a thickness of at least about 50-100 nm, preferably at least about 150 nm up to about 200 nm. The photoresists of the invention are generally flexible and can be formulated as positive or negative chemically amplified photoresists as needed.

There is recognition that many current polymers useful as photoresists significantly absorb light below 200 nm. Without wishing to be bound to any theory, it is believed that by adding one or more electronegative groups to such polymers, it is possible to substantially reduce or avoid unwanted light absorbance, particularly below 170 nm and especially 157 nm. As discussed below, more preferred electronegative groups generally include or consist of halogen, particularly fluoro, although other electronegative groups also will be suitable such as perfluoroalkyl, perfluoroalkylene, cyano, nitro, sulfinyl and sulfonyl. Particularly preferred electronegative groups within the scope of this invention are conjugated systems, particularly mono- or polycyclic aromatic systems such as phenyl, that are substituted by at least one electronegative group, particularly halogen, especially fluoro and halogenated lower alkyl such as fluorinated lower alkyl.

Resists of the invention that contain a polymer as disclosed can produce highly resolved robust relief images.

Accordingly, in one aspect, the invention provides polymers (sometimes referred to herein Group I) that may contain distinct repeat units as follows:

1) polymer backbone that comprising a plurality of carbon-carbon bond units,

2) a first electronegative group preferably capable of withdrawing electrons away from the polymer backbone; and optionally

3) a second electronegative group, which may be the same or different than the first electronegative group.

In preferred embodiments, the first electronegative group includes at least one electronegative atom, typically halogen, usually less than about twenty (20) of such atoms. A preferred halogen is fluorine although in some invention embodiments, use of other halogen atoms or nitrile may be more desirable.

In another preferred embodiment, the second electronegative group includes at least one cyano group, usually including less than about five (5) of such groups with about one (1) group being generally preferred.

It will be appreciated that when a particular polymer already has acceptable adhesion and/or etch resistance characteristics, addition of the second electronegative group to the polymer may not always be necessary. However in embodiments in which particularly good adhesion and etch resistance is required, polymers having the second electronegative group will be especially useful.

Without wishing to be bound by any theory, it is believed the combined use in polymers of the invention of i) the first electronegative group; and ii) the second electronegative group can achieve a significant reduction in sub-200 nm wavelength absorbance, particularly sub 170 nm and especially 157 nm while still imparting to the polymer good resistance to plasma etchants. See the Examples and discussion that follows. Such etch resistance can be critical to achieve desired results in high performance applications, e.g. forming highly resolved sub-half micron or sub-quarter micron resist features.

Preferred polymers of the invention (including Group I polymers) include those that contain at least one additional distinct unit (e.g. terpolymers, tetrapolymers or pentapolymers) such as an additional, distinct group consisting of hydrogen, an electronegative group such as halogen or an acid labile group. The additional distinct unit can be covalently bonded to the polymer as needed, e.g., bonding to the first electronegative group, the polymer backbone, or in some cases both groups.

In embodiments in which the additional distinct unit is the acid labile group, suitably at least one and sometimes two distinct polymer units may contain such acid labile groups. Preferred acid labile groups are those recognized in the field and include those specific groups provided below. More preferred photoacid-labile groups feature negligible absorbance below 200 nm, preferably below about 170 nm and especially about 157 nm, particularly when present as a distinct unit of the polymers described herein. Additionally preferred acid labile groups are compatible with standard labile group protection chemistries and are readily removed using conventional deprotection manipulations.

Particular polymer backbone units according to the invention include those that incorporate phenolic residues e.g. novolaks (e.g. cresol-based novolak polymers) and poly(vinylphenols) and such polymers with optional additional units such as a fluorine-containing monomer (a fluorine-containing monomer or polymer units sometimes referred to herein as a Teflon monomer of a Teflon unit), polyethylene, and alicyclic units such as norbornene and adamantyl. A fluorinated monomer will typically contain a source of unsaturation. Additional suitable fluorinated unsaturated monomers, including fluorinated alcohols, are disclosed below.

More particular polymer backbones include one of the aforementioned monomers as a polymerized first repeat unit, and a polymerized second repeat unit comprising one of the monomers. Preferably, the first and second repeat units are distinct from one another although for some applications they may be the same. For instance, the first repeat unit can be unsubstituted, and the second repeat unit can have one or more non-hydrogen repeat units, e.g. electronegative repeat units. Alternatively, the first and second repeat units each can have one or more non-hydrogen ring substituents, but where the non-hydrogen substituent(s) of the first repeat unit is different than the non-hydrogen substituent(s) of the second repeat unit.

It is emphasized that the scope of the present invention is not limited to the aforementioned specific polymers and monomeric polymer units. That is, the invention can be usefully employed with a wide spectrum of polymers and co-polymers to withdraw electrons from carbon-carbon bonds that absorb (or potentially absorb) below 200 nm, preferably below 170 nm and especially at 157 nm. The invention can thus be used to design new or improve existing polymers and photoresists having minimal absorbance in the sub-200 nm range.

Specifically, the invention can be used to add one or more functionalized aromatic ring substituents to a wide variety of existing polymers for use in photoresist imaging in the sub-200 nm and particularly 157 nm range. See the PCT/US99/21912 application for illustrative fluorinated polymers that can be so adapted.

As discussed above, polymers of the invention may contain repeat units having electronegative substituents in addition to phenyl or other aromatic units, e.g. repeat units of Teflon, alicyclic groups such as adamantyl and norbornene, ethylene, and the like, which have one or more electronegative substituents such as a halogen particularly fluorine, or haloalkyl particularly fluoro(C₁₋₁₂alkyl) such as —CF₃. The addition of one or preferably at least two different of such additional units can assist control of lithographic properties of the polymer, particularly with respect to light absorbance, etch resistance, dissolution contrast, adhesion and resolution.

In particular, for reducing light absorbance below 200 nm and particularly at 157 nm, the first Teflon, norbornene, or ethylene monomer unit desirably includes at least one of the first electronegative groups previously mentioned. Particular groups of interest include those comprising at least one halogen, typically fluorine, or haloalkyl such as halo(C₁₋₁₂alkyl), particularly fluoro(C₁₋₁₂alkyl) especially perfluoro(C₁₋₁₂alkyl). In embodiments in which good adhesion and/or etch resistance is desired, the first monomer (e.g. not substituted with any non-hydrogen substituents) can be polymerized and a second unsaturated fluorinated monomer such as a Teflon compound, norbornene, or ethylene monomer can be polymerized as well. As discussed, it will often be highly useful to include one or more of the second electronegative groups as a component of the second monomer unit, preferably an acrylonitrile group, and/or an acrylic ester group preferably an acrylic group containing one or more halogens.

Thus, in one particular aspect of the invention, polymers are provided that contain at least two distinct polymerized unsaturated fluorinated monomers such as a Teflon compound, norbornene, or ethylene repeat units. In this aspect of the invention, such polymers may also include at least one acid labile group. Such groups can be a substituent of one or both of the two distinct repeat units, or as a polymer repeat unit separate from those units.

In one invention embodiment, such an acid-labile group may be present together with the two or more distinct polymerized unsaturated fluorinated monomers such as a Teflon compound, ethylene, or norbornene repeat units.

The invention provides more specific polymers in which at least one of the distinct units includes an acid labile group. For instance, the polymer may contain an ethylene or norbornene unit to which is bound to a carbon atom of the unit backbone at least one acid-labile group, usually one of such groups. In another embodiment, the polymer includes bound to the first electronegative group, at least one acid labile group with one of said groups being generally preferred. In still another embodiment, the polymer with the acid-labile group bound to the unit backbone further includes another acid-labile group (the same or different from the first acid-labile group bound to the backbone) bound to the first electronegative group.

In instances in which the acid-labile group is bound to an electronegative group consisting of a halogenated alcohol, preferably that binding will be via an oxygen (oxy) bond. In this embodiment, the acid-labile group suitably protects the alcohol oxygen atom from unintended reaction. Thus, especially preferred acid-labile groups will be useful in conventional protection and deprotection chemistries.

Generally preferred polymers of the invention (including Group I polymers) include those that contain at least one repeat unit that comprises an acid-labile group, often two of such repeat units, which units also include the first and second electronegative groups mentioned above. Polymers of the invention also may contain multiple, distinct repeat units, e.g. two distinct repeat units, that each comprise an acid-labile group, which contains these groups.

The invention provides for polymers (including Group I polymers) polymers that include one or more of the above features. For instance, preferred are terpolymers, tetrapolymers, pentapolymers, hexapolymers, septapolymers or other higher order polymers that contain at least the above groups 1) through 3), i.e. 1) (polymer backbone group); 2) (first electronegative group, preferably including at least one halogen such as fluorine; and 3) (second electronegative group including acrylonitrile). Preferably, at least one of the distinct units 1) through 3) has acid labile groups with binding of the groups to at least units 1) and 2) being preferred. In embodiments in which multiple acid labile groups are employed, such groups can be the same or different as needed.

In another aspect, the invention provides polymers (Group II) that contain at least two of the following repeat units:

1) a polymer backbone comprising a first phenolic ring substituted with hydrogen or at least one first electronegative group, the backbone further comprising at least one methylene unit optionally substituted with at least one second electronegative group,

2) a group comprising a second phenolic ring substituted with hydrogen or at least one third electronegative group,

3) a group comprising a third phenolic ring substituted with hydrogen or at least one fourth electronegative group,

wherein, each of the electronegative groups is the same or different, and

each of the phenolic rings is the same or different.

Illustrative electronegative groups of the above-mentioned Group II polymers are generally the same as those exemplified for the Group I polymers discussed previously. Thus, particular electronegative groups of interest include at least one electronegative atom, typically halogen, usually less than about twenty (20) of such atoms. A preferred halogen is fluorine although other halogens may be more desirable for some uses of the invention.

In a more particular embodiment of the foregoing Group II polymer, the group including the second phenolic ring further includes a methylene unit optionally substituted with a fifth electronegative group the same or different from the first, second, third or fourth electronegative groups. In another embodiment, the second phenolic ring of the Group II polymer includes at least one sixth electronegative group which group can be the same or different from the previous electronegative groups (first, second, third, etc.). In yet another embodiment, the group including the third phenolic ring further includes at least one seventh electronegative group which group can also be the same or different from the prior electronegative groups.

In a preferred embodiment, the group comprising the polymer backbone of the Group II polymer includes at least one polymerized cresol unit (e.g. a trifluoromethylphenol) with a methylene bridge between polymer units provided by a condensation polymerization with formaldehyde to provide a novolak of the invention. Thus in a more specific example of the invention, the polymer includes a first substituted novolak repeat unit, a second substituted novolak repeat unit and a third substituted novolak repeat unit in which each of the units is preferably different from the other unit.

As an illustration, a particular Group II polymer includes the first substituted novolak repeat unit comprising at least one of the first and second electronegative groups; the second substituted novolak repeat unit includes at least one of the third, fifth and sixth electronegative groups, and the third substituted novolak repeat unit includes at least one of the fourth and seventh electronegative groups. Preferably, each of the foregoing novolak repeat units includes all of the mentioned electronegative groups. Also preferably, at least one of the first, second, third, fourth, fifth, sixth or seventh electronegative groups include of consist of halogen which halogen is typically fluorine.

The invention provides for more specific Group II polymers that include one or more of the above features. For instance, preferred are terpolymers, tetrapolymers, pentapolymers and hexapolymers that include at least the above groups 1)-3), i.e. 1) (polymer backbone group preferably comprising substituted novolak) preferably including a methylene carbon substituted with one or two halogens, especially two fluorine atoms; 2) (second phenolic ring group preferably substituted with at the third and sixth electronegative groups, preferably halogenated lower alkyl such as fluorinated lower alkyl); and 3) (third phenolic ring group preferably substituted with the fourth and fifth electronegative group, preferably halogenated lower alkyl such as fluorinated lower alkyl).

Preferred polymers of the invention (i.e. Group I and II polymers) are preferably employed in photoresists imaged at sub 200 nm, preferably below 170 nm, and especially at 157 nm. In some embodiments, the resin will be substantially free of unsubstituted phenyl or other unsubstituted aromatic groups. A resin will be substantially free of unsubstituted aromatic groups if it contains less about 5 mole percent, more preferably less than about 4, 3, 2, 1 or 0.5 mole percent unsubstituted aromatic groups based on total polymer units. In embodiments in which such groups are present including certain preferred Group II polymers, such groups will include at least one suitable electronegative group such as a halogen atom, halogenated lower alkyl, halogenated lower alkyl alcohol, or halogenated ring system. As discussed fluorine and fluorinated groups are generally preferred.

The invention also contains blends of resins, and positive and negative photoresists that contain such resin blends. Preferred resin blends of the invention comprise: 1) an aromatic polymer having repeat units with electronegative substituents such as halogen particularly fluorine, or haloalkyl such as halo(C₁₋₁₂alkyl) particularly fluoro(C₁₋₁₂alkyl) such as —CF₃, especially novolak and poly(vinylphenol) polymers, as discussed above; and 2) polymers that are substantially free of aromatic units (e.g. less than 5, 4, 3, 2 or 1 mole percent aromatic units) and preferably comprise alicyclic units such as norbonyl, adamantyl and the like, which contain one or more electronegative substituents such as halogen and haloalkyl substituents discussed immediately above with respect to polymers 1) of the blend. Suitable polymers of type 2) of such resin blends include those disclosed in PCT/US99/21912. The relative amounts of polymers of types 1) and 2) in a blend may suitably vary relatively widely, e.g. 10 parts by weight of an aromatic polymer of type 1) relative to 1 part by weight of a non-aromatic polymer of type 2), to 10 parts by weight of a non-aromatic polymer of type 2) to 1 pat by weight of an aromatic polymer of type 1).

Other preferred resin blend members also contain two distinct polymers that each has aromatic substitution such as aromatic polymers with electronegative substitution as described immediately above.

The invention also includes resins that are substantially free of aromatic units, and positive and negative photoresists that contain such resins. The resins are preferably substituted with one or more electron-withdrawing substituents, such as halogen particularly fluoro, and haloalkyl, particularly halo(C₁₋₁₂alkyl) such as fluoro(C₁₋₁₂alkyl) e.g. —CF₃.

For certain aspects of the invention, resists will be preferred that contain higher order polymers as described herein, particularly terpolymers (i.e. the polymer comprises at three distinct repeat units), tetrapolymers (i.e. the polymer contains at least four distinct repeat units) and pentapolymers (i.e. the polymer comprises at least five dist9inct repeat units).

Polymers of the invention may be used in both positive-acting and negative-acting photoresist compositions. Generally preferred are chemically-amplified positive-acting resists and chemically-amplified negative resists, i.e. negative-acting resist compositions which undergo a photoacid-promoted crosslinking reaction to render exposed regions of a coating layer of the resist less developer soluble than unexposed regions, and positive-acting resist compositions which undergo a photoacid-promoted deprotection reaction of acid labile groups of one or more composition components to render exposed regions of a coating layer of the resist more soluble in an aqueous developer than unexposed regions.

Polymers and resists of the invention also will be useful for imaging at other wavelengths such as sub-300 nm wavelengths, particularly at about 248 nm.

The invention also includes synthetic methods for producing polymers of the invention. In particular, methods are provided for synthesis of a halogenated, preferably fluorinated, phenolic polymer including novolak polymers and polymers containing vinylphenol and optionally substituted styrene units. The synthesis includes oxidation of the preformed polymer e.g. with a strong oxidant such as CrO₃ in the presence of acid followed by halogenation of the polymer e.g. fluorination with a suitable fluorinating agent such as HF. The halogenation particularly fluorination can suitably halogenate methylene bridges between phenolic units (in the case of a novolak) or halogenate carbon atoms of the polymer backbone (such as a polymer comprising optionally substituted styrene units). The preformed polymer suitably may not be halogenated or substantially free of halogen substitution prior to the oxidation step. A polymer will be substantially free of halogen substitution if les than 5, 4, 3, 2, 1 or 0.5 weight percent of the total polymer consists of halogen atoms.

Additional synthetic methods of the invention include formation of a halogenated particularly fluorinated resol compound e.g. resol oligomer having a molecular weight of about 3,000, 2,000, 1,500, 1000 or less, or about 800, 700, 600, 500, 400 or 300 or less. That formed resol can be reacted e.g. in the presence of acid to provide a higher molecular weight polymer, e.g. a fluorinated novolak having a molecular weight (Mw) of about 50,000 or less, more typically about 40,000 or less, even more typically about 25,000, 20,000, 15,000, 10,000 or 5,000 or less.

The invention also provides methods for forming relief images, including methods for forming a highly resolved relief image such as a pattern of lines where each line has essentially vertical sidewalls and a line width of about 0.40 microns or less, and even a width of about 0.25, 0.20 or 0.16 microns or less. The invention further provides articles of manufacture comprising substrates such as a microelectronic wafer substrate or liquid crystal display or other flat panel display substrate having coated thereon a polymer, photoresist or resist relief image of the invention.

Other aspects of the invention are disclosed infra.

### BRIEF DESCRIPTION OF THE DRAWINGS

FIG. 1 shows the SEM image of the developed resist of Example 14 which follows.

### DETAILED DESCRIPTION OF THE INVENTION

Particular polymers of the invention include one or more repeat units that comprise at least one electronegative group which group typically includes an electronegative atom such as a halogen (F, Cl, Br, I). Fluorine is an especially preferred electronegative atom. In cases in which the electronegative group is halogen, usually less than about twenty five (25) atoms will be employed, preferably less than about twelve (12) of such atoms with less than about six (6) to nine (9) often being useful.

Additionally preferred electronegative groups include a plurality of atoms arranged as a molecular group. Such a group typically includes at least one electronegative atom, often more than one of such atoms up to a fully substituted molecular group. In this embodiment, preferred electronegative groups include halogenated lower alkyl; halogenated lower alcohol, cyano, or O—C—O. In preferred embodiments the lower alkyl and lower alcohol groups are nearly or fully substituted with halogen, typically fluorine.

As discussed, certain Group I polymers of this invention can include an acid-labile group. Preferably, such groups include, but are not limited to, branched or straight-chain lower alkyl, lower alkyl ether including (alkoxy)ethyl vinyl ether, saturated and unsaturated cyclic ethers e.g., tetrahydropyranyl ether, lower cycloalkanes, and lower alkyl silanes, all of which may be provided by reaction of a hydroxy group with a vinyl ether; photoacid-labile esters such as t-butyl esters and the like.

Preferred polymers of the invention include a halogenated, particularly fluorinated phenol substituent. As referred to herein, the term “phenol substituent”, “phenol group” or other similar term is inclusive of phenol groups in “masked” form, i.e. where the phenolic hydroxy group is bonded to a group such as acetoxy or photoacid-labile group such as to form an acetal group or an ester group. Additionally, by stating that the phenol is halogenated, particularly fluorinated, it is meant that a halogen such as fluorine can be a direct phenol ring substituent, or the phenol ring has a substituent where that substituent is halogenated, particularly fluorinated such as a haloalkyl, particularly haloC₁₋₁₂ alkyl, e.g. —CF₃, —CF₂CF₃ and other perhalogenated C₁₋₁₂alkyl, —CF₂CH₃, —CF₂CFH₂, —CF₂CH₂CH₃, and the like. A halogenated phenol also may comprise a mixture of different types of halogen ring substituents, e.g. one or more fluoro substituents and one or more haloC₁₋₁₂ alkyl such as one or more CF₃ substituents.

A halogenated phenol group suitably may have one or more halogen substituents, typically 1, 2, 3 or 4 halogen substituents such as fluoro, more typically 1, 2 or 3 halogen substituents. For instance, suitable halogenated phenolic units of polymers of the invention include the following units 1, 2, 3, 4 and 5:

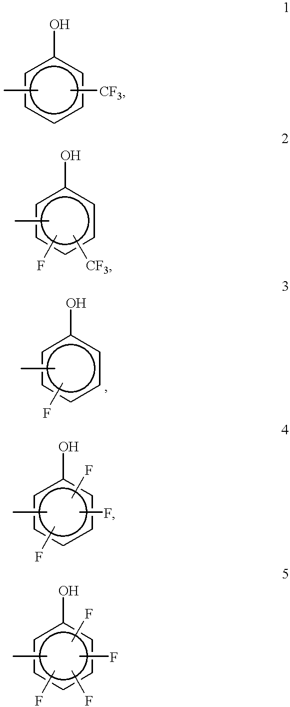

As indicated above, preferred polymers of the invention include novolaks, such as polymers that contain repeat units of the following Formula A:

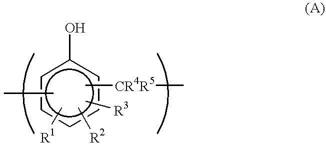

wherein in the above Formula A each R¹, R² and R³ may be the same or different and may be hydrogen or a non-hydrogen substituent provided at least one of R¹, R² and R³ is a halogenated substituent, particularly a fluorinated substituent such as F or CF₃ or other perhaloalkyl;

R⁴ and R⁵ may be the same or different and may be hydrogen or a non-hydrogen-substituent including a halogen substituent such as F, perhaloC₁₋₁₂alkyl including perfluoroC₁₋₁₂alkyl such as CF₃, aryl substituted with halo such as particularly fluorophenyl or fluoronaphthyl particularly pentafluorophenyl and trifluoromethylphenyl, and the like, and other non-hydrogen substituent such as aryl particularly phenyl and the like, alkyl such as C₁₋₁₂alkyl, alkoxy such as C₁₋₁₂ alkoxy, cyano, etc.

Novolaks of the invention may contain a single type of halogenated phenolic unit such as only 2,3-difluorophenolic units, or a mixture of different phenolic units, e.g. 2, 3, 4, 5, 6, 7, 8, 9, or 10 or more different halogenated phenolic units, such as a mixture of halogenated phenolic units of the above Formula A.

Novolaks of the invention optionally may specially purified after synthesis for use in a photoresist of the invention. For instance, a polymer of the invention may be fractionated to remove undesired fractions, e.g. low molecular weight fractions. Use of a more narrow molecular weight distribution polymer may be especially preferred for polymers containing photoacid-labile moieties.

Phenolic polymers, including novolak polymers of the invention may be synthesized by a variety of routes. An acid-promoted condensation of reaction components is one preferred route, e.g. reaction of an aromatic compound preferably having electronegative substitution such as fluorine or fluoro(C₁₋₁₂alkyl) e.g. —CF₃ and comprising a hydroxy substituent such as a phenol, cresol, resorcinol, an oxymethyl phenyl compound including bisoxymethyl phenols, and a carbonyl-containing compound such as formaldehyde or the like, or other keto-containing compounds such as an aromatic aldehyde e.g. salicyaldehyde, benzaldehyde, and substituted benzaladehydes e.g. 2-chlorobenzaldehyde, 3-hydroxybenzaldehyde, 4-hydroxybenzaldehyde, 2-methoxybenzaldehyde, 3-nitroaldehyde and the like, preferably having electronegative substitution such as fluorine or fluoro(C₁₋₁₂alkyl) e.g. —CF₃. The reaction is conducted in the presence of a suitable acid, e.g. a mineral acid such as HCl, or sulfuric acid, or an organic acid such as formic acid and the like. More vigorous reaction conditions typically will be required for condensation of an aromatic aldehyde relative to an aliphatic aldehyde such as formaldehyde, e.g. the reaction can be run at reflux in a suitable non-interfering organic solvent such as acetone and the like. See generally U.S. Pat. Nos. 5,932,389 and 5,529,880, both to Zampini and assigned to the Shipley Company, for a discussion of suitable synthetic procedures and reagents. A divalent metal catalyst also may be employed in the polymer synthesis.

Preferred Group I polymers of the invention include those of the following Formula II:

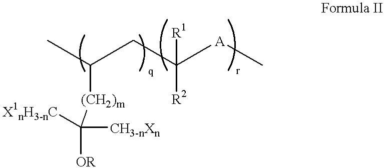

wherein R and R¹ are each independently are hydrogen or an acid labile group;

R² is the second electronegative group,

X and X¹ are each independently halogen the same or different, preferably fluorine atom,

A is an optionally substituted methylene, mono- or polyalicyclic group such as norbornene,

n and m are each independently 0, 1, 2, or 3; and

q and r are each mole percent of the depicted polymer units and are each greater than 0.

In a more specific embodiment of the Group I polymer represented by Formula I, R and R¹ are each independently —H, t-butyl, 2,2,-dimethyl-3-methylpropyl, or compounds represented by the following structures:

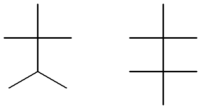

1,1,2-trimethylpropyl, 1,1,2,2-tetramethylpropyl,

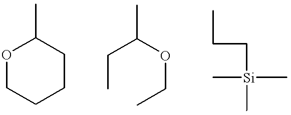

tetrahydropyranyl, i-ethoxypropyl, ethyl-2-trimethylsilanyl,

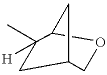

2-oxa-bicylco[2.2.1]hept-6-yl (exoisomer) including alkylated derivatives thereof such as 2-methyl-,

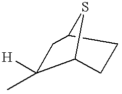

7-thia-bicyclo[2.2. 1 ]hept-2-yl (endoisomer) including alkylated derivatives thereof such as 2-methyl-,

as well as suitable ketals, acetal, formals, and ortho esters the same or different, R² is acrylonitrile,

X and X¹ are each fluorine; and

n is 1, 2 or 3 and m is 0 or 1.

Preferred Group II polymers of the invention are represented by the following Formula III:

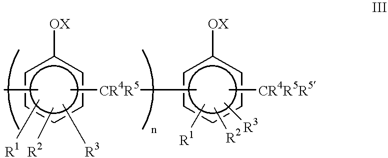

wherein in Formula III each R¹, R² and R³ may be the same or different and may be hydrogen or a non-hydrogen substituent provided at least one of R¹, R² and R³ is a halogenated substituent, particularly a fluorinated substituent such as F or CF₃ or other perhaloalkyl such as perhalo(C₁₋₁₂alkyl) including perfluoro(C₁₋₆alkyl);

each R⁴, R⁵ and R^{5′} may be the same or different and may be hydrogen or a non-hydrogen-substituent including a halogen substituent such as F, perhaloC₁₋₁₂alkyl including perfluorC₁₋₁₂alkyl such as CF₃, aryl substituted with halo such as particularly fluorophenyl or fluoronaphthyl particularly pentafluorophenyl and trifluoromethylphenyl, and the like, and other non-hydrogen substituent such as aryl particularly phenyl and the like, alkyl such as C₁₋₁₂alkyl, alkoxy such as C₁₋₁₂ alkoxy, cyano, etc.;

X is hydrogen or non-hydrogen substituent particularly to form with the depicted oxygen an ester, ether, acetal or the like;

n is greater than zero and is the mole percent of the depicted polymer unit.

Preferred polymers according to Formula III, above, feature phenolic substituents arranged in a meta configuration.

Preferred monomers for use in synthesis of polymers of the invention include those of the following formulae 1 through 13:

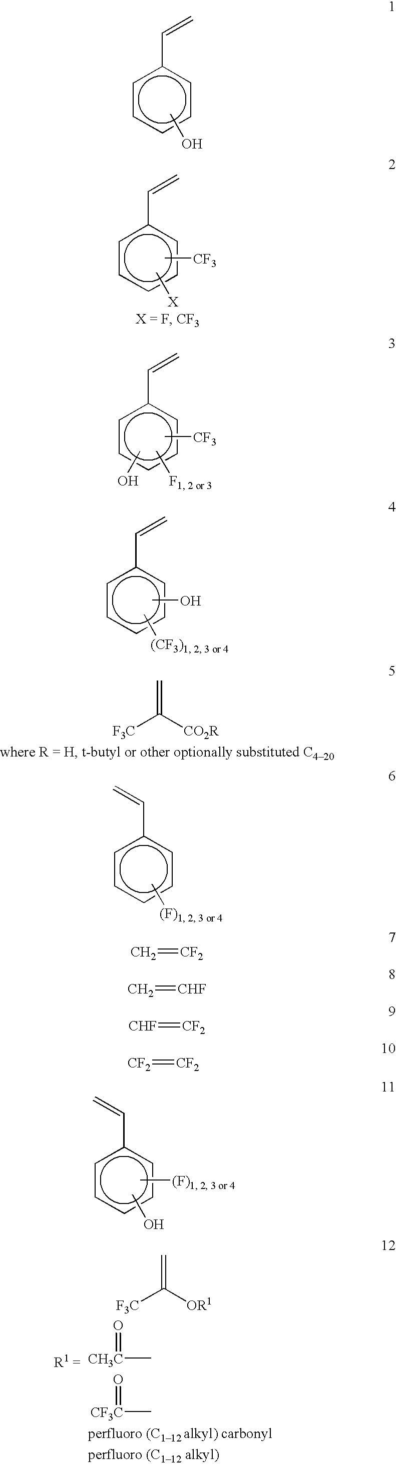

Additional specifically suitable units of polymers of the invention include the following units 14 through 17, where the wavy line indicates covalent linkage to the polymer. Such units can be readily provided by polymerization of the corresponding vinyl or other alkene monomers:

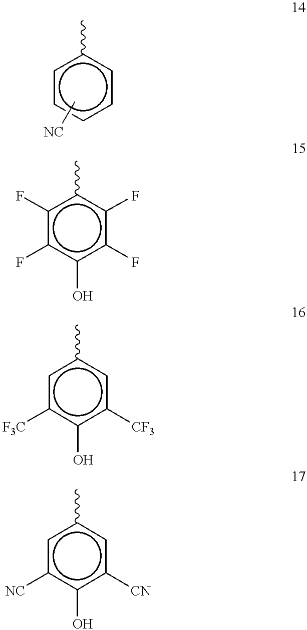

Specifically preferred phenolic polymers of the invention include the following, where synthetic routes are also depicted. For some of the polymers, mole percents of the depicted polymer units based on total polymer units are shown as x, y and/or z.

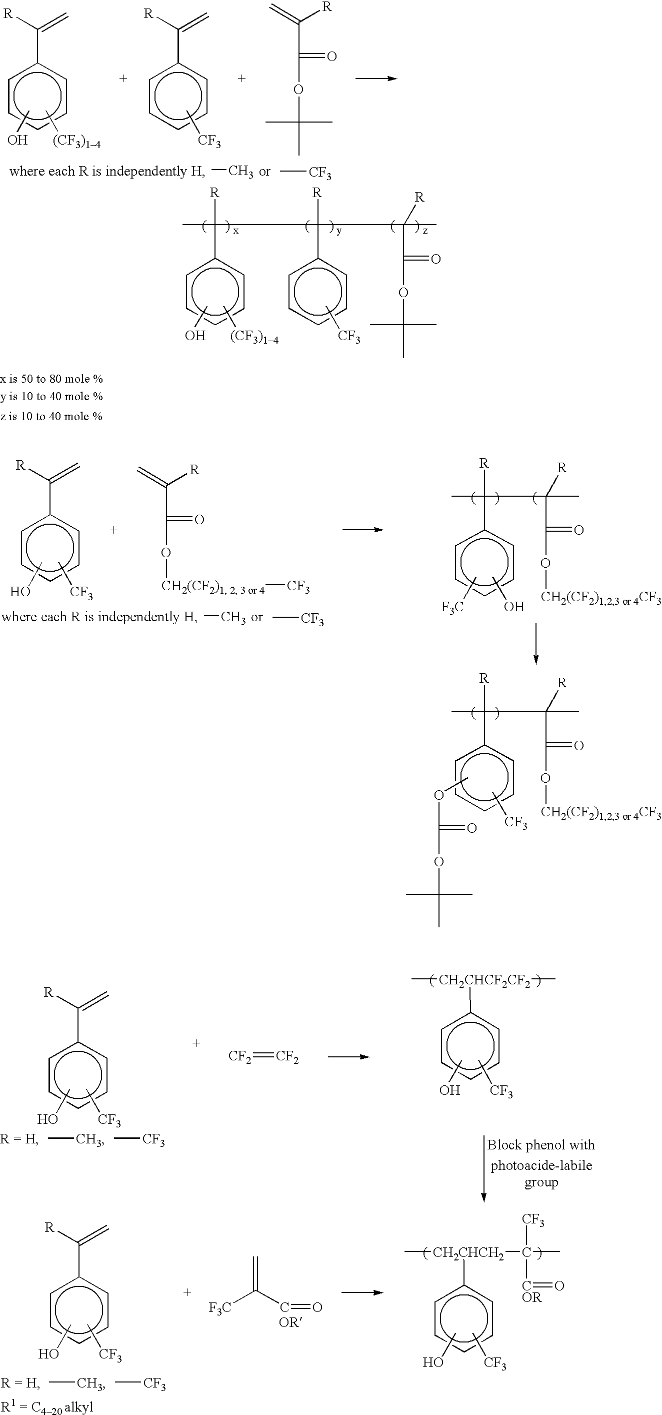

Preferred Group I polymers of the invention provide a positive working, single layer resist system based on fluorinated alcohol chemistry. The Group II polymers provide a single-layer positive resist based on a unique fluorinated novolak chemistry suitable for production at critical dimensions down to 70 nm. Specifically preferred positive photoresists will feature low absorbance, functionalized matrix polymer, capable of being rendered aqueous base soluble in the presence of a strong acid, a photoacid generator solvents and additives.

An objective of the invention is to provide new polymers that exhibit the required absorbance, dissolution characteristics and etching resistance necessary to produce a high resolution photoresist. In one aspect, the invention features polymers and photoresist compositions that include functionalized phenolic polymers. Such polymers include electron withdrawing groups such as fluorine containing moieties. Illustrative of such polymers are the Group II polymers mentioned above. In addition, the present invention provides a new class of copolymers exemplified by the Group I polymers mentioned previously. One such example of Group I polymers is based on acrylonitrile and vinyl hexafluoroisopropanol.

It has been found that by using substituted phenols and fluorinated alcohols, it is generally possible to avoid difficulties such as resist swelling during development and adhesion failure that can arise when carboxylic acids are used to impart the necessary solubility in developer. It will be recognized that such polymers can be functionalized as necessary and as such, formulated as positive or negative chemically amplified photoresists.

The presence of one or more of the electronegative groups disclosed herein, particularly halogen and especially fluorine can significantly reduce excessive absorption of 157 nm.

As discussed, the invention provides two general classes of resist polymer, which can be functionalized to produce positive-tone resists: Group I: resists based on fluorinated alcohols with acidities comparable to that of phenol and Group II resists made from fluorinated phenolic materials, specifically substituted with trifluoromethyl groups to avoid absorbing energy at 157 nm, thus taking advantage of the transparency “window” in the energy region between the transition to the second excited singlet and radiative ionization. These materials will offer low absorbance and permit use in conventional developers. Furthermore, it is believed that the enhanced fluorine content will reduce the surface tension in the developed resist, thereby reducing the tendency of the resist pattern to collapse during the rinse.

Initial studies of polymer materials at 157 nm indicate that one challenge to designing and building a high resolution resist is the absorbance of the polymer itself. See Kunz et al., Proc. SPIE-Int. Soc. Opt. Eng. (1999), 3678 (Pt. 1, Advances in Resist Technology and Processing XVI), 13-23. Phenolic, acrylic, and entirely aliphatic polymers (e.g., polyethylene or polynorbornene) were reported to have prohibitive absorbance.

The following are preferred monomers to produce Group I polymers of this invention.

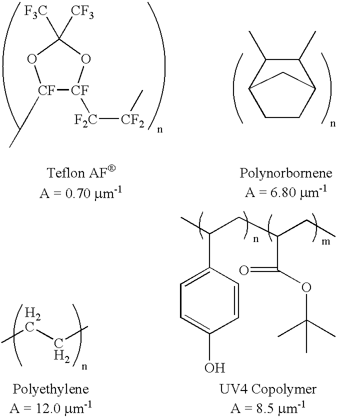

Resins of the invention suitably contain polymerized units of any one or more of acrylonitrile (AN, I), vinyl hexafluoroisopropanol (VHFI, II) and allyl hexafluoroisopropanol (AHFI, III).

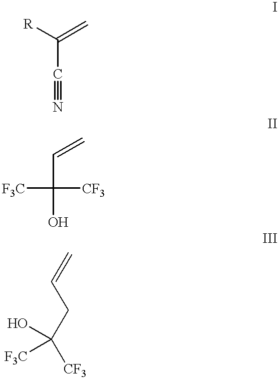

In the above structures I, II and III, R may suitably be —H, —CH₃, —F, —CF₃ and may be substituted appropriately to provide reactivity and impart as low an absorbance as possible. Polymers of acrylic monomers with α-trifluoromethyl acrylonitrile are known, as are polymers of α-fluoroacrylonitrile. For the latter, Q-e values were determined to be Q=0.43 and e=1.28. Poly-fluoroacrylonitrile undergoes dehydrofluorination followed by cyclization of the contiguous nitrile moieties at approximately 200° C.

Preferred polymers of the invention include Group I polymers having the following formulae:

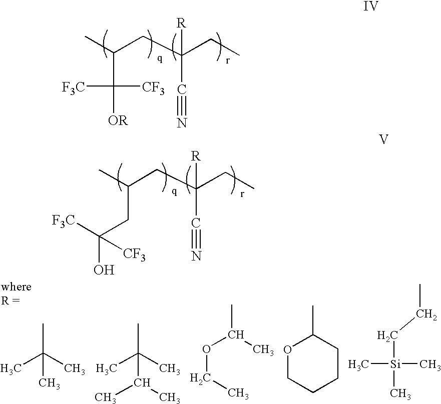

as well as other acid labile groups. The latter three protecting groups can be particularly for 157 nm imaging because of lower absorbance and more facile deprotection chemistry. Preferred deprotection occurs by acidolysis during a post-exposure-bake step in reactions similar to the following:

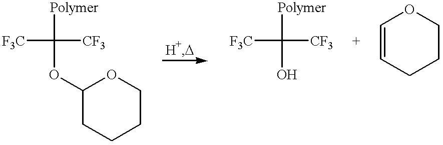

The acid-labile tetrahydropyanyl ether is shown above for illustrative purposes; other deblocking groups may be more preferred, particularly for 157 nm imaging.

In one preferred aspect of the invention, Group II polymers include substituted novolak and polyhydroxystyrene resins. Suitable polymers and the synthesis thereof are as follows:

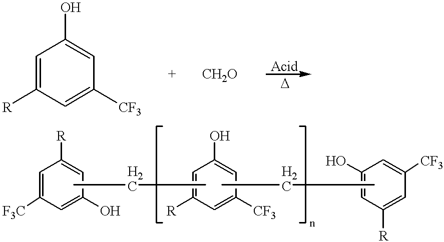

where R=H, —CF₃. The meta isomer and the 3,5 bis(trifluoromethyl) phenol are the only two fluorinated phenols that can form a novolak polymer because the ortho and para isomers decomposed at the temperatures required to carry out the polymerization reaction. The phenolic monomers are commercially available.

In another embodiment, polymers of the invention may be substantially free of aromatic groups. More particularly, preferred polymers that are substantially free of aromatic groups contain less than about 5 mole percent aromatic groups, more preferably less than about 1 or 2 mole percent aromatic groups, still more preferably less than about 0.1, 0.02, 0.04 and 0.08 mole percent aromatic groups and even more preferably less than about 0.01 mole percent aromatic groups. Particularly preferred polymers are completely free of aromatic groups. At least many aromatic groups can be highly absorbing of sub-200 nm radiation and thus can be undesirable for polymers used in photoresists imaged with such short wavelength radiation.

Suitable polymers that are substantially or completely free of aromatic groups suitably contain acrylate units such as photoacid-labile acrylate units as may be provided by polymerization of methyladamanatylacrylate, methyladamanylmethacrylate, ethylfencylacrylate, ethylfencylmethacrylate, and the like; fused non-aromatic alicyclic groups such as may be provided by polymerization of a norbornene compound or other alicyclic compound having an endocyclic carbon-carbon double bond; an anhydride such as may be provided by polymerization of maleic anhydride; and the like. Repeat units of such polymers preferably have electron-withdrawing substituents such as halogen particularly fluorine, and haloalkyl particularly halo(C₁₋₁₂alkyl) especially fluoro(C₁₋₁₂alkyl) e.g. —CF₃.

It also has been found that polymers of the invention may contain aromatic groups and will not exhibit excessive absorbance of short wavelength exposure radiation, such as sub-170 nm or sub-160 nm radiation, particularly 157 nm exposure radiation. As discussed above, such aromatic groups preferably have one or more ring substituents that are electron-withdrawing groups, e.g. halogen particularly fluoro; or perhaloalkyl, particularly perfluoroalkyl such as trifluoromethyl.

In a more particular embodiment, the invention provides polymers that may be substantially free of unsubstituted aromatic groups or aromatic groups of any type and include the following units:

| | | |
|---|---|---|
| 1) | 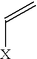 | in which X is cyano, fluorinated lower alkyl e.g., CF₃ with the proviso that X is not fluorine, |
| 2) | 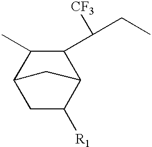 | in which R₁ is an electronegative group other than fluoroalkyl, |
| 3) | 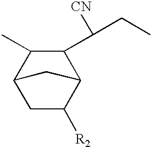 | in which R₂ is hydrogen, an acid group, blocked acid group, or R₂ is —(CH₂)ₙ—C(CF₃)₂—O—Y with the proviso that Y is hydrogen, an acid cleavable group e.g., t-Boc, and n is 0, 1, or 2, |
| 4) | 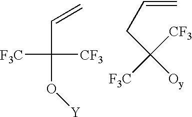 | in which Y is defined in 3) above, |
| 5) | 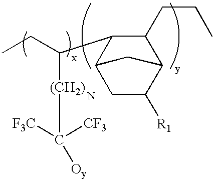 | in which R₁ is defined in 2) above, Y and n are defined in 3) above, |
| 6) | 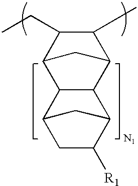 | in which n1 is 0, 1, or 2, preferably 0, |
| 7) | 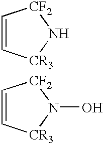 | in which R₃ is F or H with F being preferred; and |
| 8) | 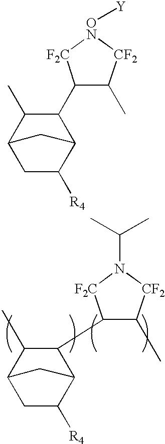 | in which Y is the same as defined in 3) above, and R₄ is the same as R as defined in 2) above. |

Additional monomer units in accord with the invention can be made by the following synthetic routes:

| | | |
|---|---|---|
| 1) | 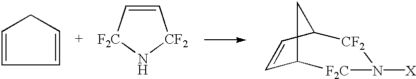 | in which X is H, OH, Y, or OY in which Y is defined as H, acid cleavable group, t-Boc |
| 2) | 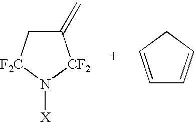 | |
| 2) | 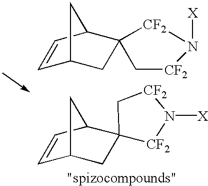 | in which X is fluorinated lower alkyl or cyano with the proviso X is not fluoro. |

Polymers of the invention can be prepared by a variety of methods. One suitable method is an addition reaction which may include free radical polymerization, e.g., by reaction of selected monomers to provide the various units as discussed above in the presence of a radical initiator under an inert atmosphere (e.g., N₂ or argon) and at elevated temperatures such as about 70° C. or greater, although reaction temperatures may vary depending on the reactivity of the particular reagents employed and the boiling point of the reaction solvent (if a solvent is employed). Suitable reaction solvents include e.g. tetrahydrofuran, ethyl lactate and the like. Suitable reaction temperatures for any particular system can be readily determined empirically by those skilled in the art based on the present disclosure. A variety of free radical initiators may be employed. For example, azo compounds may be employed such as azo-bis-2,4-dimethylpentanenitrile. Peroxides, peresters, peracids and persulfates also could be employed.

As discussed, various moieties may be optionally substituted, including groups of Formulae I, II and III. A “substituted” substituent may be substituted at one or more available positions, typically 1, 2, or 3 positions by one or more suitable groups such as e.g. halogen (particularly F, Cl or Br); C₁₋₈ alkyl; C₁₋₈ alkoxy; C₂₋₈ alkenyl; C₂₋₈ alkynyl; hydroxyl; alkanoyl such as a C₁₋₆ alkanoyl e.g. acyl and the like; etc Preferred substitution groups will generally include or consist of at least one halogen atom, preferably fluorine such as fluorinated lower alkyl, perfluoroalkyl, and perfluoroalkylene, fluorinated cycloalkyl, and fluorinated ethers and esters including fluorinated cyclic ethers and fluorinated cyclic esters.

Examples of alkyl and lower alkyl include methyl, ethyl, propyl, butyl, pentyl, hexyl and the like, preferably methyl, ethyl and propyl. Suitably alkyl and lower alkyl groups will contain from 1 to about 8 carbon atoms, more typically 1 to about 6 carbon atoms.

Preferred optionally substituted styrene and substituted styrene groups will be substituted with one or more electronegative groups such as a halogen, particularly fluorine at available ring position. Substituted vinylphenol is a preferred styrene group. Fluorovinylphenol including monofluorophenol (—C₆H₃FOH), difluorophenol (—C₆H₂F₂OH), trifluorophenol (—C₆HF₃OH), and tetrafluorophenol (-C₆F₄0H) are preferred polymer units.

Certain preferred polymers for use in the invention will include both phenolic units and phenyl units that do not have hydroxy substitution. However, preferably both the phenolic units and the styrene units will have one or more electronegative substituents, particularly halo, especially fluoro.

Preferably a polymer of the invention will have a weight average molecular weight (Mw) of about 800 or 1,000 to about 100,000, more preferably about 2,000 to about 30,000, still more preferably from about 2,000 to 15,000 or 20,000, with a molecular weight distribution (Mw/Mn) of about 3 or less, more preferably a molecular weight distribution of about 2 or less. Molecular weights (either Mw or Mn) of the polymers of the invention are suitably determined by gel permeation chromatography.

Polymers of the invention used in photoresist formulations should contain a sufficient amount of photogenerated acid labile ester groups to enable formation of resist relief images as desired. For instance, suitable amount of such acid labile ester groups will be at least 1 mole percent of total units of the polymer, more preferably about 2 to 40, 50, 60 or 70 mole percent, still more typically about 3 to 30, 40, 50, 60 or 70 mole percent of total polymer units. See the examples which follow for exemplary preferred polymers.

A variety of photoacid-labile groups may be employed in resists of the invention. For instance, as discussed above, phenolic groups of polymers of the invention may be reacted with vinyl ethers such as ethyl vinyl ethyl ether to provide a photoacid-labile acetal group. Photoacid-labile ester groups such as provided by polymerization of t-butyl methacrylate or t-butyl trifluoromethylacrylate also may be co-polymerized with other polymer units.

Preferred resists of the invention include those that contain a polymer that incorporates a fluoroalcohol, particularly hexafluoroisopropanol. A fluoroalcohol is generally incorporated into a polymer via polymerization of a corresponding vinyl monomer. Such monomers are commercially available or can be readily prepared. For instance, vinyl hexafluoroisopropanol (VHFIP) is suitably made as shown immediately below. Also preferred is use of the hexafluoroalcohol monomer having an additional methylene (CH₂) group adjacent to the vinyl group (i.e. CH₂═CHCH₂C(CF₃)₂OH), which can be made with the corresponding Grignard reagent (i.e. CH₂═CHCH₂MgBr).

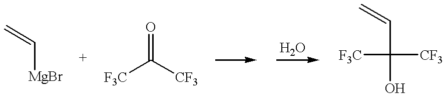

Polyacrylonitrile was also found to have relatively low absorbance at 157 nm. The monomer will impart both good adhesion and etching resistance to the resist. The polymer is synthesized with an acid-labile protecting group such as the one shown below and formulated with a photoacid generator to yield a positive-tone resist. A fluorine-containing acrylonitrile monomers also can be substituted for acrylonitrile, as represented by R in the scheme immediately below. Also preferred is use of the hexafluoroalcohol monomer having an additional methylene (CH₂) group adjacent to the vinyl group (i.e. CH₂═CHCH₂C(CF₃)₂OH)

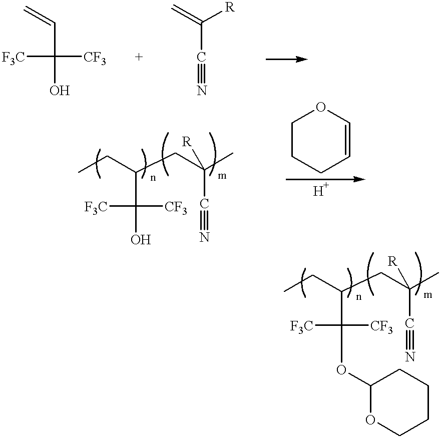

Negative photoresists of the invention are synthesized in the same manner, except the unprotected polymer (i.e. no photoacid-labile groups) is directly formulated with a photoacid generator and an aminoplast crosslinker. After exposure and post-exposure-bake, the resist will be crosslinked sufficiently to become insoluble in the exposed region but will remain soluble in the unexposed region, as generally depicted in the exemplary scheme immediately above. Also preferred polymers for use in negative resists are those as shown below, but where an additional methylene group (CH₂) is interposed between the polymer backbone and quaternary carbon (—C(CF₃)₂OH).

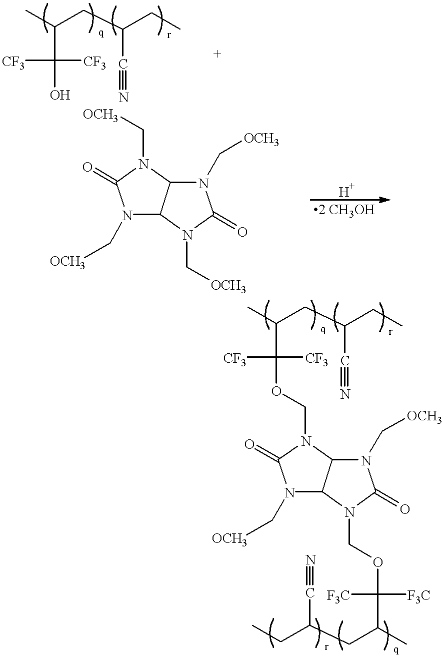

Polymers for use in resists also may be readily synthesized from commercially available monomers, such as exemplified in the following reaction scheme:

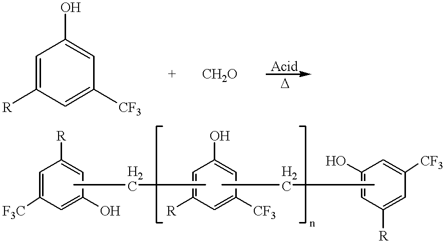

where in those above structure R is suitably hydrogen, halogen such as fluoro, C₁₋₈alkyl such as methyl, C₁₋₈haloalkyl such as —CF₃. These materials can be further modified, as desired, e.g. by fluorinating the methylene bridges as described below in Example 1. The polymer then can be substituted with an acid-labile protecting group (e.g. an acetal or ester group grafted onto the ring hydroxy group) and formulated with a photoacid generator to yield a positive-tone resist material.

Polymers made with these systems will be made from known monomers. The fluorinated alcohol monomers are made according to the following reactions:

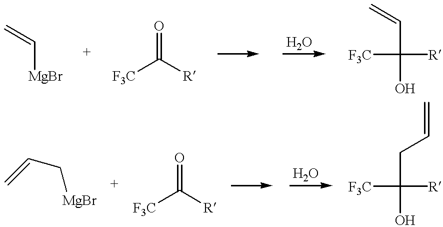

In the above reactions, R′ can be —H, —CH₃ or —CF₃ and will be varied to adjust the acidity and Tg of the polymer. In addition, there is some indication that etching resistance can be influenced by the choice of R′. Starting materials for these reactions are all commercially available.

If these monomers are made in ethers such as tetrahydrofuran, a product likely to be isolated from the reaction will be the hydrogen-bonded ether adduct. For example, one obtains the THF adduct by distilling vinyl hexafluoroisopropanol (VHFIP) from THF. The etherate boils at approximately 100° C. while the pure compound boils at 72-74° C.

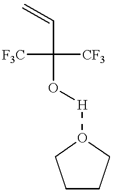

Pure VHFIP is obtained by distilling the etherate from concentrated sulfuric acid.

These monomers are suitably copolymerized with methacrylonitrile or acrylonitrile using standard free-radical chemistry.

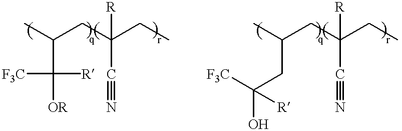

In the scheme immediately above, R can be —H, —F, —CH₃ or —CF₃ and will be chosen to minimize absorbance by withdrawing electron density from the polymer backbone. The polymers thus formed will be used either directly or functionalized with conventional deprotection chemistry such as the ethoxy ethyl group as shown below.

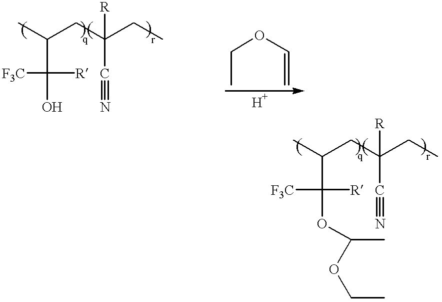

While the (ethoxy)ethyl vinyl ether protecting group is shown, the specifics of the deprotection chemistry will be dictated by considerations of outgassing during exposure, post-exposure-bake time and temperature sensitivity and hydrolytic stability as it pertains to resist shelf-life. Other acid-labile groups include but are not limited to the following:

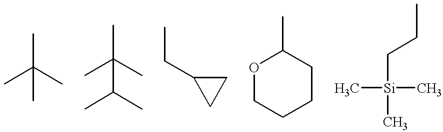

Halogenated (including fluorinated) novolak polymers discussed above can be modified further to reduce absorbance by fluorinating the methylene bridges. This is accomplished first by oxidation:

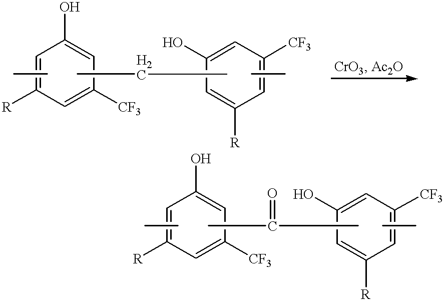

then by fluorination.

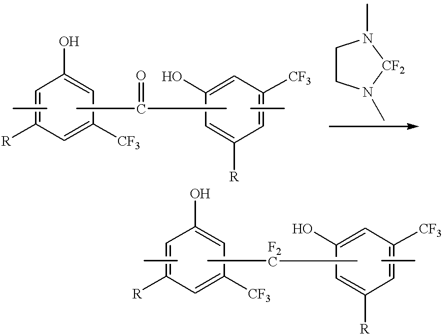

As shown above, the sequential steps of oxidation and fluorination provide the —CF₂-linker between phenolic groups.

Such novolak polymers can be protected with photoacid-labile groups and undergo deprotection reactions as generally discussed above, such as with the hexafluoroisopropanol moieties. Deprotection can for instance during the post-exposure-bake step as follows:

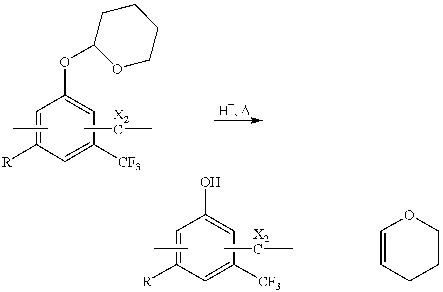

The above shown protected polymers can be made by known procedures, usually involving the reaction of the phenol with a vinyl ether such as dihydropyran under acidic conditions.

Also suitable are resists that contain polymers having phenolic units substituted with one or more electronegative groups (e.g. fluoro or other halogen, haloalkyl such as fluoroalkyl particularly —CF₃). Such substituted polymer units can be significantly transparent to short wavelength radiation such as sub-170 nm radiation particularly 157 nm.

Fluorinated phenolic polymers will be synthesized from commercially available monomers according the known reaction:

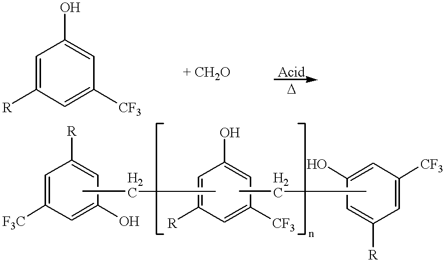

where R=H, —CH₃. These materials can be further modified, if necessary, by fluorinating the methylene bridges. The polymer will be substituted with a deprotecting group as in the case above to form the basis of a positive resist.

Methylene bridges also can be fluorinated, such as by the following route, which includes (1) oxidation of the methylene groups:

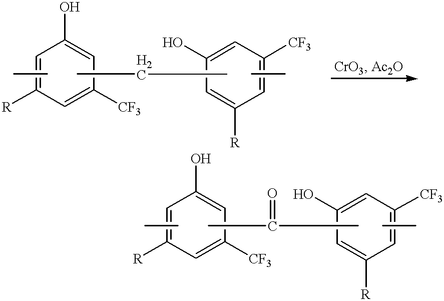

(2) fluorination of the ketone moieties to yield the difluoromethylene moiety:

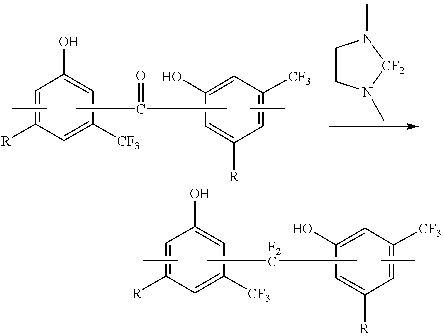

A suitable acid labile protecting group such as discussed above can be substituted at the phenolic hydroxyl groups. This is shown for the case of the tetrahydropyranyl moiety below:

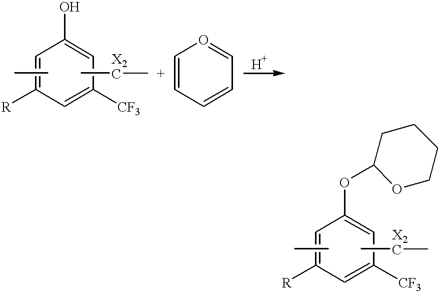

In the above reaction, X suitably can be either —H or —F. As above, acid is generated in the exposed resist film. The deprotection reaction occurs during the post-exposure bake step and is essentially the reverse of that shown.

As discussed above, the polymers of the invention are highly useful as a resin binder component in photoresist compositions, particularly chemically-amplified positive resists. Photoresists of the invention in general comprise a photoactive component and a resin component that comprises a polymer as described above.

The resin component is suitably used in an amount sufficient to render a coating layer of the resist developable with an aqueous alkaline developer.

Preferred resist compositions of the invention also comprise a photoacid generator (i.e. “PAG”) that is suitably employed in an amount sufficient to generate a latent image in a coating layer of the resist upon exposure to activating radiation. As discussed, a wide variety of photoacid generators (PAGs) can be used with the present invention, including both ionic and non-ionic photoacid generator compounds.

More particularly, preferred PAGS for use in resists of the invention include onium salt compounds including iodonium and sulfonium compounds; and non-ionic PAGs such as imidosulfonate compounds, N-sulfonyloxuimide compounds; diazosulfonyl compounds and other sulfone PAGs including α,α-methylenedisulfones and disulfonehydrazines, nitrobenzyl compounds, halogenated particularly fluorinated non-ionic PAGs. Preferred PAGs for use in resists of the invention also include those that do not have aromatic substitution.

Specifically suitable PAGs include the following, where the depicted iodonium and sulfonium compounds may suitably have any of the depicted counter anions.

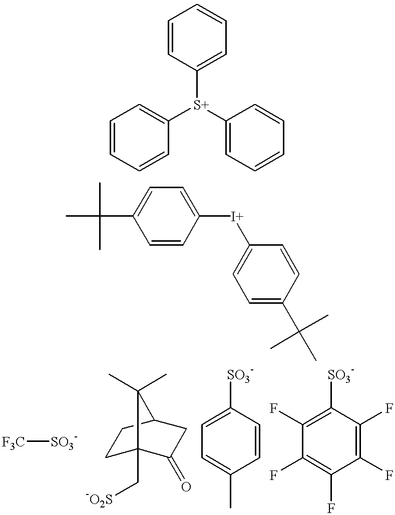

Suitable PAGs for use in resists of the invention also include imidosulfonates such as compounds of the following formula:

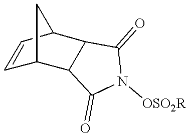

wherein R is camphor, adamantane, alkyl (e.g. C₁₋₁₂ alkyl) and perfluoroalkyl such as perfluoro(C₁₋₁₂alkyl), particularly perfluorooctanesulfonate, perfluorononanesulfonate and the like. A specifically preferred PAG is N-[(perfluorooctanesulfonyl)oxy]-5-norbornene-2,3-dicarboximide.

Other known PAGS also may be employed in the resists of the invention. Particularly for 193 nm imaging, generally preferred are PAGS that do not contain aromatic groups, such as the above-mentioned imidosulfonates, in order to provide enhanced transparency.

A preferred optional additive of resists of the invention is an added base, particularly tetrabutylammonium hydroxide (TBAH), or tetrabutylammonium lactate, which can enhance resolution of a developed resist relief image. For resists imaged at 193 nm, a preferred added base is a hindered amine such as diazabicyclo undecene or diazabicyclononene. The added base is suitably used in relatively small amounts, e.g. about 0.03 to 5 percent by weight relative to the total solids.

Photoresists of the invention also may contain other optional materials. For example, other optional additives include anti-striation agents, plasticizers, speed enhancers, etc. Such optional additives typically will be present in minor concentrations in a photoresist composition except for fillers and dyes which may be present in relatively large concentrations, e.g., in amounts of from about 5 to 30 percent by weight of the total weight of a resist's dry components.

The resists of the invention can be readily prepared by those skilled in the art. For example, a photoresist composition of the invention can be prepared by dissolving the components of the photoresist in a suitable solvent such as, for example, cyclohexanone, 2-heptanone, ethyl lactate, ethylene glycol monomethyl ether, ethylene glycol monomethyl ether acetate, propylene glycol monomethyl ether; propylene glycol monomethyl ether acetate and 3-ethoxyethyl propionate. Typically, the solids content of the composition varies between about 5 and 35 percent by weight of the total weight of the photoresist composition. The resin binder and photoactive components should be present in amounts sufficient to provide a film coating layer and formation of good quality latent and relief images. See the examples which follow for exemplary preferred amounts of resist components.

The compositions of the invention are used in accordance with generally known procedures. The liquid coating compositions of the invention are applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions of the invention are suitably applied to substrates conventionally used in processes involving coating with photoresists. For example, the composition may be applied over silicon wafers or silicon wafers coated with silicon dioxide for the production of microprocessors and other integrated circuit components. Aluminum-aluminum oxide, gallium arsenide, ceramic, quartz, copper, glass substrates and the like are also suitably employed.

Following coating of the photoresist onto a surface, it is dried by heating to remove the solvent until preferably the photoresist coating is tack free. Thereafter, it is imaged through a mask in conventional manner. The exposure is sufficient to effectively activate the photoactive component of the photoresist system to produce a patterned image in the resist coating layer and, more specifically, the exposure energy typically ranges from about 1 to 100 mJ/cm², dependent upon the exposure tool and the components of the photoresist composition.

As discussed above, coating layers of the resist compositions of the invention are preferably photoactivated by a short exposure wavelength, particularly a sub-300 and sub-200 nm exposure wavelength, and even sub-170 nm wavelength. As discussed above, 157 nm is a particularly preferred exposure wavelength. However, the resist compositions of the invention also may be suitably imaged at higher wavelengths. For example, a resin of the invention can be formulated with an appropriate PAG and a sensitizer if needed and imaged at higher wavelengths such as about 193 nm or 248 nm.

Following exposure, the film layer of the composition is preferably baked at temperatures ranging from about 70° C. to about 160° C. Thereafter, the film is developed. The exposed resist film is rendered positive working by employing a polar developer, preferably an aqueous based developer such as quaternary ammonium hydroxide solutions such as a tetra-alkyl ammonium hydroxide solution; various amine solutions preferably a 0.26 N tetramethylammonium hydroxide, such as ethyl amine, n-propyl amine, diethyl amine, di-n-propyl amine, triethyl amine, or methyldiethyl amine; alcohol amines such as diethanol amine or triethanol amine; cyclic amines such as pyrrole, pyridine, etc. In general, development is in accordance with procedures recognized in the art.

Following development of the photoresist coating over the substrate, the developed substrate may be selectively processed on those areas bared of resist, for example by chemically etching or plating substrate areas bared of resist in accordance with procedures known in the art. For the manufacture of microelectronic substrates, e.g., the manufacture of silicon dioxide wafers, suitable etchants include a gas etchant, e.g. a halogen plasma etchant such as a chlorine or fluorine-based etchant such a Cl₂ or CF₄/CHF₃ etchant applied as a plasma stream. After such processing, resist may be removed from the processed substrate using known stripping procedures.

All documents mentioned herein are incorporated herein by reference. The following non-limiting examples are illustrative of the invention.

### EXAMPLE 1

### Synthesis of Fluorine Containing Phenolic-formaldehyde Novolak Resin

To a 100 mL 3-necked round bottom flask equipped with a magnetic stirrer, addition funnel, thermometer and oil bath was added 16.2 g of trifluoro-m-cresol and 33 g of 80% sulfuric acid. The mixture was then heated while stirred. At 50° C., 8.93 g of 37% formalin was slowly added over a 12 minute period. During the addition the reaction temperature quickly rose to 81° C. At 93° C. the product begun to precipitated from solution. The mixture was then heated within the temperature range of 99 to 108° C. for about three hours. Upon cooling the aqueous layer was decanted and the product washed with copious amounts of de-mineralized water. The product was then washed with 500 mL de-mineralized water containing 2.5 g of sodium bicarbonate, collected on a filter, rinsed with water and air dried. The solid was then dissolved in 60 g of acetone to produce a clear solution. After the solution was filtered through a glass wool plug it was added drop wise to 500 mL de-mineralized water precipitating the novolak product. The aqueous layer was decanted and the tacky precipitate allowed to partially air dry before fully dried at 40° C. under vacuum. About 18.4 g of product was recovered having a weight average molecular weight of 3650 Daltons and a polydispersity of 1.98.

### EXAMPLE 2

### Use of Fluorinated Novolak

A 5 wt. % solution of the fluorinated novolak of Example 1 was prepared and filtered. The polymer solution was spin coated on CaF₂ disks and silicon wafers. After such coating, the coating layer was baked at 90 seconds at 120° C. The absorbance of the dried polymer layer was obtained by measuring samples of several thicknesses with a vacuum or spectrometer. The normalized absorbance at 157 nm was 4.0 per micron of thickness.

A reference novolak polymer used in the production of I-line photoresists had an absorbance at 157nm of 7.8 per micron thickness.

### EXAMPLE 3

### Photoresist Preparation and Lithographic Processing

A photoresist of the invention is prepared by mixing the following components with amounts expressed as weight percent based on total weight of the resist compositions:

| Resist components | Amount (wt. %) |
|---|---|
| Resin binder | 15 |
| Photoacid generator | 3 |
| Ethyl lactate | 81 |

The resin binder is the fluorinated novolak of Example 4 below. The photoacid generator is p-toluenesulfonyl-trifluoromethanesulfonyl-diazomethane. Those resin and PAG components are admixed in the ethyl lactate solvent.

The formulated resist composition is spin coated onto HMDS vapor primed 4 inch silicon wafers and softbaked via a vacuum hotplate at 90° C. for 60 seconds. The resist coating layer is exposed through a photomask at 248 nm, and then the exposed coating layers are post-exposure baked at 110° C. The coated wafers are then treated with 0.26N aqueous tetramethylammonium hydroxide solution to develop the imaged resist layer and provide a relief image.

### EXAMPLE 4

### Synthesis of 30% blocked EVE-novolak(trifluoromethyl-substituted)

In a 100 mL three-neck round bottom flask fitted with vacuum distillation apparatus were added 10.00 g (57.47 mmol-eq.) of (trifluoromethyl)-substituted novolak and 30 g of propylene glycol methyl ether acetate (PGMEA). The residual water was removed by azeotropic vacuum distillation with PGMEA at 45° C. (bath temperature). Total 20.97 g of PGMEA was collected in a receiver and a dry ice-vacuum trap. The concentration of the polymer solution was maintained as 25% (w/w). To the reaction solution was added 0.015 g (0.15% w/w of polymer) of trifluoroacetic acid (TFA), and the reaction mixture was stirred for an hour at 20° C. To the reaction mixture was slowly added 1.33 g (18.39 mmol) of ethyl vinyl ether (EVE), and the polymer solution was stirred for 17 h at 20° C. A small quantity (ca. 6 mL) of the reaction solution was sampled and treated with 0.7 g of conditioned IRA-67 ion exchange resin for 2 h.

The solution was filtered and spun onto a silicon wafer to produce a 1455 Å thick film. The film dissolved at a rate of about 22 Å/sec. when immersed into a 0.26N tetramethylammonium hydroxide solution.

### EXAMPLE 5

### Radical Terpolymerization of 4-acetoxystyrene, (Trifluoromethyl)-Substituted Styrene and t-butyl Acrylate

In a 100 mL three-neck round bottom flask were added 2.83 g (17.43 mmol) of 4-acetoxystyrene, 1.00 g (5.81 mmol) of (trifluoromethyl)-substituted styrene, 0.74 g (5.81 mmol) of t-butyl acrylate and 12 mL of dry isopropyl alcohol (IPA). The reaction vessel was then purged with nitrogen and the reaction mixture was kept under inert atmosphere. The reaction solution was then brought to a gentle reflux at 95° C. (bath temperature). To the reaction mixture was added 0.19 g (1.16 mmol, 4 mol % of monomer) of azo-bis-2,2′-isobutyronitrile (AIBN) dissolved in 1.5 mL of anhydrous acetonitrile. The reaction mixture was then refluxed with stirring for 18 h. To the refluxing polymer solution was slowly added 3.13 g (40.67 mmol) of ammonium acetate dissolved in 3 mL of deionized water. The polymer solution becomes slightly hazy but the haziness disappears in an hour. The refluxing was continued for 15 h and the solution was cooled to room temperature. To the polymer solution was added 6.10 g of conditioned IRN-77 acidic ion exchange resin, and the mixture was stirred for 2 h. The polymer solution was then filtered, precipitated in 250 mL of deionized water, and stirred for 2 h. The polymer was filtered, washed with 250 mL of deionized water with stirring for an hour, and filtered and air-dried. Vacuum drying for 24 h at 70° C. gave 3.40 g of white powder. Yield: 74%. Molecular weight: M_{w} 9900 Mₙ 5600 PD 1.75. T_{g}: 139° C. T_{d}: 183° C. Initial polymerization feed ratio was 60/20/20 (4-acetoxystyrene/(trifluoromethyl)-substituted styrene/t-butyl acrylate) and the determined actual composition was 63/19/18. The terpolymer composition was calculated by quantitative ¹³C NMR experiments.

### EXAMPLE 6

### Synthesis if Tetrahydropyronyl (THP) Protected Fluorine Containing Novolak

In a 100 mL three-neck round bottom flask equipped with a dropping funnel are added 5.00 g (28.74 mmol) of F-Novolak prepared according to the procedure described in Example 1 above (Mw=1400) and 20 mL of ethyl acetate. The mixture is stirred until homogeneous solution is obtained. To the solution are added 2.42 g (28.74 mmol) of dihydropyran and 2 drops of HCl. The reaction mixture is stirred for 24 h at 25° C. The reaction mixture is then diluted with 100 mL of dichloromethane and washed with aqueous NaCl solution and water. The organic phase is then dried over MgSO₄ and the solvent evaporated. Vacuum drying for 48 hours at room temperature gives about 5.20 g (70.2% yield) of a viscous product.

### Example 7

### Synthesis of Ethoxymethyl Ether Protected F-novolak

In a 250 mL three-neck round bottom flask equipped with a dropping funnel are added 10.00 g (57.47 mmol) of F-Novolak prepared according to the procedure described in Example 1 and 20 mL of dry THF. The mixture is stirred until a clear solution is obtained. To the solution is added 0.41 g (17.24 mmol) of sodium hydride powder. The mixture is stirred for 3 h at room temperature, followed by slow addition of 1.63 g of chloromethyl ethyl ether in 5 mL of dry THF over a 30 min. period. The reaction mixture is then stirred for 3 h at room temperature before heating up to 70° C. After 24 h, the white salt is removed by filtration and the filtrate is precipitated in 800 mL of deionized water. The collected precipitate is re-dissolved in 200 mL of dichloromethane. The organic phase is washed with two portions of 100 mL of water and dried over sodium sulfate. The solvent is removed by a rotary evaporator and the product further dried for 48 h under vacuum at 40° C. to give 10.9 g of blocked polymer.

### Example 8

### Synthesis of 30% Ethyl Vinyl Ether Blocked F-novolak

In a 100 mL three-neck round bottom flask fitted with a vacuum distillation apparatus are added 10.00 g of F-novolak prepared according to the procedure described in Example 1 and 30 g of propylene glycol methyl ether acetate (PGMEA).The residual water is removed by an azeotropic vacuum distillation with PGMEA at 45° C (bath temperature). Total 20.97 g of PGMEA is collected in a receiver and a dry ice-vacuum trap. The concentration of the polymer solution is maintained at about 25% (w/w). To the reaction solution is added 0.015 g of trifluoroacetic acid (TFA), and the reaction mixture stirred for about an hour at 20° C. To the reaction mixture is slowly added 1.33 g of ethyl vinyl ether (EVE), and the polymer solution stirred for about 17 h at 20° C. The solution is treated with a conditioned IRA-67 ion exchange resin for 2h. The solution is then filtered and the filtrate concentrated under reduced pressure. Overnight vacuum drying at 40° C. gives about 7.83 g of a brown viscous product in about 69.6% yield. Gel permeation chromatography shows the product to have a weight average molecular weight of 1760 and a number average molecular weight of 1220 Daltons. Vacuum ultraviolet spectroscopic measurements shows the product to have an absorption of about A₁₅₇: 4.55/μm.

### EXAMPLE 9

### Synthesis of Fluorine Containing Novolak Resin Using Methane Sulfonic Acid as Catalyst

To 500 mL resin kettle equipped with an oil bath, paddle stirrer, thermometer and reflux condenser are added 97.2 g (0.6 mole) of trifluoromethyl-m-cresol and 36.7 g of 37% formaldehyde. The mixture is then heated. At about 65° C. about 52.7 g of methanesulfonic acid is gradually added and the addition continued until a reaction exotherm is observed at about 92° C. The batch temperature rises to about 114° C. before it begins to decline. The acid addition is then resumed and continued to completion. The reaction mixture is then allowed to reflux for about 4 hours. While the reaction mixture is still hot about 77 g of trifluoromethylbenzene and 200 mL of water containing 3 g of sodium bicarbonate are added and the mixture vigorously agitated. After the aqueous layer is removed the organic solution is washed twice with 200 mL portions of fresh de-mineralized water. The organic solution is then concentrated by distilling away the solvent under atmospheric pressure. The product is further heated to about 150° C. before partial vacuum is applied. At about 170° C. 3 mmHg vacuum is applied until the batch temperature rises to about 200° C. At this point the vacuum is broken with nitrogen and the product poured into an aluminum pan and allowed to cool. About 81.3 g of product is obtained having a weight average molecular weight of about 2460 Dalton and a molecular weight dispersity of about 1.84. The dissolution rate of the resin in 0.26 N tetramethyl ammonium hydroxide is about 15800 A/sec.

### EXAMPLE 10

### Synthesis of t-BOC Protected F-novolak

To a 250 mL three-neck round bottom flask equipped with a dropping funnel are added 30.00 g of (trifluoromethyl)-substituted novolak of Example 8 and 80 mL of dry THF. The mixture is stirred until a clear solution is obtained. To the solution is added 8.58 g (62.07 mmol) of anhydrous potassium carbonate, followed by the slow addition of 11.29 g (51.72 mmol) of di-t-butyl dicarbonate in 20 mL of dry THF. The reaction mixture is stirred for 48 h at room temperature. The solution is filtered and precipitated in 1500 mL of de-ionized water. The filtered precipitate is dissolved in 300 mL of dichloromethane and washed twice with 200 mL of de-ionized water. The organic phase is dried over anhydrous sodium sulfate and the solvent removed by use of a rotary evaporator. Vacuum drying for 24 h at 45° C. gives 31.5 g of a white solid (90% yield). The dissolution rate of the t-BOC blocked novolak in 0.26N tetramethyl ammonium hydroxide is 1.5 A/sec.

### EXAMPLE 11

### Photoresist Composition Comprising of t-BOC Protected F-novolak.

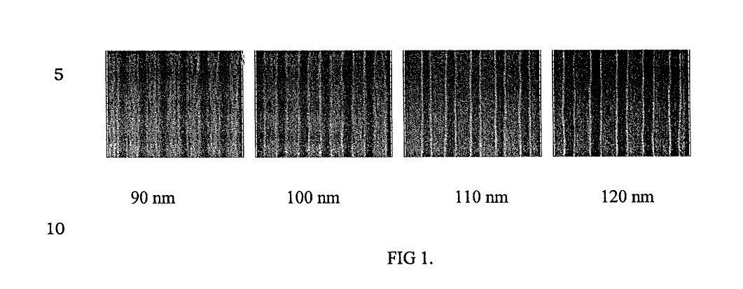

An ethyl lactate solution comprising of 7.312 weight % of a 30% t-BOC protected F-novolak prepared according to the procedure of Example 10, 0.64 weight % di(t-butyl)phenyl iodonium triflate, 0.032 weight % tetrabutylammonium hydroxide, 0.016 weight % of RO8 surfactant and 92 weight % ethyl lactate is filtered through a 0.2 mμ filter and spin coated unto an 8 inch silicon wafer to produce a 680 Å film. The film is soft baked at 80° C. for 60 seconds and exposed to 157 nm radiation using an Exitech 0.60 NA, 0.70 s. The exposed film is then post-exposed baked at 80° C. for 60 seconds and then spray developed with LDD-26W tetramethylammonium hydroxide developer, rinsed and dried. The resulting images were then analyzed using scanning electron microscopy. The developed resist images are shown in FIG. 1 of the drawings (semidense lines 1:1.5 pitch).

### EXAMPLES 12-17

The following synthesis Examples 12 to 17 demonstrate an alternative synthesis approach to a fluorinated novolak. This approach employs a two step process: (a) formation of a fluorinated resol intermediate and (b) the acid catalyzed conversion of the resol to the fluorinated novolak of the invention. This approach facilitates the syntheses of a wide range of resin structures and branching densities, resins with higher glass transition temperature, better control of resin molecular weight with minimal trifluoromethyl group hydrolysis.

### EXAMPLE 12

### Synthesis of a Fluorinated Resol

To a 500 mL Erlenmeyer flask is added a solution comprised of 26.0 g of sodium hydroxide and 120 mL of water. To this solution is added, in small portions, 97.2 g (0.6 mole) of 3-(trifluoromethyl)phenol followed with the addition of 146 g of 37% formaldehyde solution. The reaction mixture is heated to 80° C. and kept at this temperature for about 40 hours. While still warm the product solution is filtered and added drop wise into a stirred solution consisting of about 3 L de-ionized water, about 53.4 g of glacial acidic acid and about 10 mL of concentrated hydrochloric acid. The precipitate is collected on a filter, rinsed with water and then soaked for 3 hours in 3 L de-ionized water containing about 5 mL of concentrated hydrochloric acid. The product is collected on a filter, rinsed with water and dried first in air then at 50° C. under vacuum. About 101.7 g of a light beige solid is obtained with a weight average molecular weight of about 1850 Daltons and polydispersity of about 1.84.

The structure and composition of the fluorinated resol can be varied by the formaldehyde feed, reaction temperature and reaction time. Example 13 below is a demonstration of this process versatility.

### EXAMPLE 13

### Synthesis of a Fluorinated Resol

The same reactant ratio and basic procedure of Example 12 are used except that the maximum reaction temperature does not exceed 77° C. and the reaction time is 24 hours. Under these reaction conditions the resulting resin has a weight average molecular weight of 946 Daltons and a polydispersity of 1.43.

### EXAMPLE 14

### Synthesis of a Fluorinated Novolak

The fluorinated resol of Example 12 above was reacted with 3-(trifluoromethyl)phenol. To a 250 mL round bottom flask equipped with a thermometer and an oil bath is added 20 g of resin of Example 12 and 20 g of 3-(trifluoromethyl)phenol. The mixture is heated to 81° C. with mixing until a solution is obtained. To this solution 0.6 g of methanesulfonic acid is added and the mixture kept at about 84° C. for 4 hours. The product mixture is then diluted with about 40 mL of methanol and added drop wise to about 500 mL of de-ionized water containing about 2 g of sodium bicarbonate. The precipitate is collected, rinsed and soaked in 500 mL of de-mineralized water. Again the precipitate is collected, rinsed and partially air dried on the filter before it is placed in a 50° C. vacuum oven to complete the drying process. About 32.5 g of product is recovered having a weight average molecular weight of about 4090 Daltons and a polydispersity of about 3.66.

### EXAMPLE 15

### Synthesis of a Fluorinated Novolak

The resol of Example 13 was self-condensed in the presence of acid. To a solution comprising of 2 g of resol of Example 13 and 4g of acetic acid is added 0.2 g methanesulfonic acid. The mixture is heated in an oil bath for about 5 hours at a temperature range of 85 to 89° C. The light amber solution is added dropwise, with stirring, to about 50 mL of de-mineralized water. The precipitate is washed and soaked in several 50 mL portions of fresh water. It is then re-dissolved in 10 mL methanol and re-precipitated into 40 mL water. A small amount of sodium chloride is added to disrupt the emulsion. The precipitate is collected on a filter, washed several times with water and air dried in an evaporation dish. About 2 g of product is recovered having a weight average molecular weight of about 1420 Daltons with a polydispersity of 1.72.

### EXAMPLE 16

### Resol Oligomer of 3,5-bis(trifluoromethyl)phenol

To a 125 mL Erlenmeyer flask is added 4.36 g of sodium hydroxide and 30 mL of de-mineralized water. To the solution is then added 25 g of 3,5-bis(trifluoromethyl)phenol followed by 35.3 g of 37% formaldehyde. The reaction mixture is then heated with agitation to about 85 to 90° C. for about 60 hours. Product separation is carried out by adding the reaction mixture to about 800 mL de-mineralized water acidified with about 11 g of concentrated hydrochloric acid. The resulting oil precipitate is separated using a separatory funnel, washed with several portions on de-mineralized water and dried using a freeze drier. About 21 g of a very viscous amber oil is recovered having a weight average molecular weight of 645 Daltons and polydispersity of 1.21. HPLC analysis shows the presence of at least eight major components one of which comprised about 32% of the product mixture.

### EXAMPLE 17

### Conversion of Resol Oligomer to Novolak Resin

The resol oligomer of Example 16 was converted to a novolak resin. A mixture of 5.0 g of oligomer from Example 16 and 0.07 g of methanesulfonic acid is heated at about 93 to 95° C. for about 17 hours. Upon cooling the product mixture is dissolved in 25 mL of dichloromethane and washed with de-mineralized water. The dichloromethane solution is concentrated on the rotary evaporator to dryness. About 4 g of a light brown solid is obtained having a weight average molecular weight of about 1170 Daltons and a polydispersity of 1.22.

The above Examples 15, 16 and 17 demonstrate that the methylol groups of highly fluorinated phenols and resols are reactive and affective as intermediates to higher molecular weight fluorinated novolaks. The fluorinated resol intermediates can be reacted with a large number of un-substituted and fluorine substituted phenols to form new resin structures suitable for lithographic applications. Furthermore the resol oligomer of Example 16 can be used to raise the fluorine content of novolak resins and render them more transparent to 157 nm radiation.

### EXAMPLE 18

### Synthesis of 4-hydroxy-2,3,5,6-tetrafluorostyrene (HTFS)

In a 500 mL round bottom flask are charged 75.00 g (386.38 mmol) of pentafluorostyrene, 75.88 g (1.35 mol) of potassium hydroxide, 200 mL of t-butanol and 25 mL of water. The reaction mixture is stirred at 50 ° C. for 66 h under a nitrogen atmosphere. After cooling to room temperature, 100 mL of dichloromethane is added and stirred for 30 min. The reaction mixture is then transferred slowly into a plastic beaker containing 300 mL of dilute HCl solution (2: mixture of concentrated HCl and water) with stirring at 0° C. About 20 g of calcium chloride is also added to convert hydrogen fluoride bi-product into CaF₂ salt. About 500 mL of dichloromethane is then added to the aqueous solution and the mixture stirred for 2 h at 0° C. The organic layer is separated and the top aqueous layer is then washed twice with 200 mL of dichloromethane. The combined organic solution is washed with 200 mL of aqueous NaCl solution, rinsed with water and dried over MgSO₄. High pressure liquid chromatography shows the product is a mixture of three major components. These components are identified by subsequent analyses to consist of 4-hydroxy-2,3,5,6-tetrafuorostyrene, 4-t-butoxy-2,3,5,6-tetrafluorostyrene and pentafluorostyrene. The isolation of 4-hydroxy-2,3,5,6-tetrafuorostyrene is carried out as follows.

To the crude product mixture in dichloromethane is added 500 mL of aqueous tetramethylammonium hydroxide (a 2:1 mixture of 0.26 N tetramethylammonium hydroxide developer and water). The mixture is vigorously mixed and the bottom organic layer, A, is removed and saved for further processing. The top aqueous layer, B, is washed with two 150 mL portions of dichloromethane and then acidified with HCl until the pH reached about 2˜3. To this acidified mixture is added 500 mL of dichloromethane to extract the product. The dichloromethylene solution is then washed with 100 mL of NaCl solution, rinsed with water and dried over MgSO₄. To the filtered solution about 15 ppm of t-butylcatechol is added and the solvent removed under reduced pressure at 15° C. About 48.2 g (64.9% yield) of a light yellow liquid is obtained with a >99% purity as determined by HPLC analysis.

### EXAMPLE 19

### 4-t-Butoxy-2,3,5,6-tetrafluorostyrene

4-t-Butoxy-2,3,5,6-tetrafluorostyrene, present in the organic layer A of Example 18, is isolated and purified by distillation.

### EXAMPLE 20

### Synthesis of Poly(pentafluorostyrene)

To a 50 mL round bottom flask are charged 5.00 g (25.76 mmol) of pentafluorostyrene, 0.170 g (1.03 mmol) of AIBN radical initiator and 8.00 g of anhydrous THF. The reaction vessel is then degassed by two freeze and thaw cycles, and kept under nitrogen atmosphere. The reaction mixture is then heated with stirring at 70° C. for 18 h. To the viscous reaction mixture is added 4 mL of THF, and the solution precipitated into 600 mL of methanol. The polymer is air-dried, redissolved into 5 mL of acetone and re-precipitated into 600 mL of methanol. Upon vacuum drying for 24 h at 40° C. about 4.89 g of white powder is obtained (97.8% yield) with a weight average molecular weight (Mw)of about 14700, and a number average molecular weight of about (Mn) 6900 Daltons. The absorbance at 157 nm is about 3.76/μm

### EXAMPLE 21

### Synthesis of Poly(4-hydroxy-2,3,5,6-tetrafluorostyrene)

To a 50 mL round bottom flask are charged 10.00 g (52.08 mmol) of 4-hydroxy-2,3,5,6-tetrafluorostyrene of Example 18, 0.257 g (1.56 mmol) of AIBN radical initiator and 15.00 g of anhydrous THF. The reaction vessel is then degassed by two freeze and thaw cycles, and kept under nitrogen atmosphere. The reaction mixture is then heated with stirring at 70° C. for 18 h. To the viscous reaction mixture is added 5 mL of THF, and the solution precipitated into 800 mL of hexane. The polymer is collected and air-dried, re-dissolved in 15 mL of THF and re-precipitated into 800 mL of hexane. Vacuum drying at 40° C. for 24 h gives about 8.79 g of a white powder (88.0% yield) having a Mw of about 63300 Daltons and a polydispersity of 2.36. The polymer glass transition is about 76° C. with an absorbance at 157 nm of about 4.71/μm.

### EXAMPLE 22

### Synthesis of poly(4-t-butoxy-2,3,5,6-tetrafluorostyrene)

To a 50 mL round bottom flask are charged 5.00 g (20.14 mmol) of 4-t-butoxy-2,3,5,6-tetrafluorostyrene of Example 19, 0.099 g (0.604 mmol) of AIBN radical initiator and 10.00 g of anhydrous THF. The reaction vessel is degassed by two freeze and thaw cycles, and kept under a nitrogen atmosphere. The reaction mixture is then heat with stirring at 70° C. for 16 h. To the viscous reaction mixture is added 5 mL of THF, and the solution precipitated into 800 mL of methanol. The resulting polymer is collected on a filter, air-dried, re-dissolved in 10 mL of THF and re-precipitated in 800 mL of methanol. After vacuum drying at 40° C. for 24 h about 4.12 g of white powder (82.4% yield) is obtained. Gel permeation chromatography analysis shows the product to have a Mw of about 71390, a Mn of about 28650 Daltons. Differential scanning calorimetry shows a glass transition temperature for the polymer of about 106° C. The vacuum UV absorbance of the polymer at 157 nm is about 4.24/μm.

### EXAMPLE 23

### Synthesis of Poly(4-hydroxy-2,3,5,6-tetrafluorostyrene-co-4-t-butoxy-2,3,5,6-tetrafluorostyrene)

To a 50 mL round bottom flask are charged 2.00 g (10.41 mmol) of 4-hydroxy-2,3,5,6-tetrafluorostyrene, 3.88 g (15.62 mmol) of 4-t-butoxy-2,3,5,6-tetrafluorostyrene, 0.256 g (1.56 mmol) of AIBN and 12 g of anhydrous THF. The reaction vessel is degassed by two freeze and thaw cycles, and kept under nitrogen atmosphere. The reaction mixture is then heated with stirring at about 70° C. for about 16 h. To the viscous reaction mixture is added 5 mL of THF and the solution precipitated into about 800 mL of hexane. The polymer is collected and air-dried on the filter, re-dissolved in 10 mL of THF and re-precipitated in 800 mL of hexane. After vacuum drying at 40° C. for 24 h about 4.32 g of a white powder (73.5% yield) is obtained having a Mw of 62770 and a Mn of 28860 Daltons. The polymer composition was determined by quantitative NMR techniques to comprise of 33 mole percent of 4-hydroxy-2,3,5,6-tetrafluorostyrene and 67 mole percent of 4-t-butoxy-2,3,5,6-tetrafluorostyrene. Differential scanning calorimetry of the polymer gave a glass transition of 105° C. while the dissolution rate in a 0.26 N tetramethylammonium hydroxide developer was determined to be about 1.0A/s.

### EXAMPLE 24

### Synthesis of Poly(4-hydroxy-2,3,5,6-tetrafluorostyrene-co-t-butylmethacrylate)

To a 50 mL round bottom flask are charged 6.00 g (31.23 mmol) of 4-hydroxy-2,3,5,6-tetrafluorostyrene, 2.96 g (20.82 mmol) of t-butylmethacrylate, 0.256 g (1.56 mmol) of AIBN and 15 g of anhydrous THF. The reaction mixture is degassed by two freeze and thaw cycles, and while under an nitrogen atmosphere is heated with stirring at about 70° C. for 16 h. To the viscous reaction mixture is added 5 mL of THF and the solution precipitated into about 1600 mL of de-mineralized water. The polymer is collected and air-dried on the filter, re-dissolved in 15 mL of THF and re-precipitated into about 1600 mL de-mineralized water. The product is vacuum dries at 50° C. for 48 h to give about 7.92 g of white powder (88.4% yield) having a Mw of about 31100 and a Mn of about 13100 Daltons. The T_{g} is 99° C. as determined by DSC and the absorbance at 157 nm is 4.95/μm.

### EXAMPLE 25

### Synthesis of Poly(α-(trifluoromethyl)acrylic acid-co-2,3,4,5,6-pentafluoro styrene)

To a 50 mL round bottom flask are charged 2.50 g (17.85 mmol) of α-(trifluoromethyl)acrylic acid, 3.46 g of 2,3,4,5,6-pentafluorostyrene and 0.117 g of AIBN radical initiator. The reaction vessel is degassed using the freeze and thaw method, and kept under nitrogen atmosphere. The reaction mixture is then heated with stirring at 70° C. for 18 h. To the solidified reaction mixture is added 10 mL of THF and the mixture stirred until it completely dissolves. The product is precipitated into 800 mL of hexane, is collected on a filter and air-dried. It is then re-dissolved in 10 mL of THF and again precipitated into 800 mL of hexane . The product is collected on a filter, it is air dried followed by a final vacuum drying at 40° C. for 24 h. About 4.38 g (74% yield) of a white polymer powder is obtained having a weight average molecular weight of about 46,500 and a number average molecular weight of about 19,500 Daltons as determined by gel permeation chromatography. At 157 nm the polymer has an absorbance of 5.39/pm as determined using the Acton vacuum deep UV instrument.

### EXAMPLE 26

### Synthesis of Poly(4-hydroxy-2,3,5,6-tetrafluorostyrene-co-2-methyladamantylmethacrylate)

To a 50 mL round bottom flask are charged 2.00 g (10.41 mmol) of 4-hydroxy-2,3,5,6-tetrafluorostyrene, 1.63 g (6.94 mmol) of 2-methyladamantyl methacrylate, 0.085 g (0.521 mmol) of AIBN and 8 g of anhydrous THF. The reaction mixture is first degassed and then while under a nitrogen atmosphere is heated with stirring at about 70° C. for about 16 h. To the reaction mixture is then added 3 mL of THF and the solution precipitated into 800 mL of hexane. The polymer is vacuum dried for 24 h at 40° C. to give about 2.12 g of a white powder (58.4% yield) having a Mw of about 36890 and a Mn of about 18660 Daltons.

### EXAMPLE 27

### Synthesis of Poly(4-hydroxy-2,3,5,6-tetrafluorostyrene-co-isobornylmethacrylate)

To a 50 mL round bottom flask are charged 2.00 g (10.41 mmol) of 4-hydroxy-2,3,5,6-tetrafluorostyrene, 1.54 g (6.94 mmol) of isobornyl methacrylate, 0.085 g (0.52 mmol) of AIBN and 8 g of anhydrous THF. The mixture is degassed and while under a nitrogen atmosphere is heated with stirring at about 70° C. for 16 h. The reaction mixture is diluted with about 3 mL of THF and the solution precipitated into 800 mL of hexane. The product was collected and air dried on the filter, re-dissolved in 7 mL of THF and re-precipitated into 800 mL of hexane. The polymer was vacuum dried at 40° C. for 24 h to give about 1.82 g of a white powder (51.4% yield) having a Mw of about 31090 and Mn of about 14750 Daltons.

### EXAMPLE 28

### Synthesis of Poly(4-hydroxy-2,3,5,6-tetrafluorostyrene-co-pentafluorostyrene-co-t-butylmethacrylate)

To a 250 mL round bottom flask are charged 3.23 g (16.81 mmol, 60 mole %) of 4-hydroxy-2,3,5,6-tetrafluorostyrene, 9.544 g (2.80 mmol, 10 mole %) of pentafluorostyrene, 1.20 g (8.41 mmol, 30 mole %) of t-butylmethacrylate, 0.276 g (1.681 mmol) of AIBN and 50 g of anhydrous THF. The reactants mixture is degassed and while under a nitrogen atmosphere is heated with stirring at 70° C. for 16 h. The reaction mixture is then concentrated and slowly added into 800 mL of hexane to precipitate the polymer. After it is air dried on the filter the product is re-dissolved in 7 mL of THF and re-precipitated from 800 mL of hexane. The product was vacuum dried at 40° C. for 24 H to provide about 2.39 g of a white powder (58.0% yield) with a Mw of about 8910 and an Mn of about 5420 Daltons. Spectroscopic analysis, using both ¹³C and ¹⁹F NMR techniques, is used to determine the mole percent of monomer incorporation into the polymer. The polymerization reaction produced a terpolymer containing about 59.34 mole % 4-hydroxy-2,3,5,6-tetrafluorostyrene, about 9.91 mole % pentafluorostyrene and about 30.75 mole % of t-butylmethacrylate. Additional characterization indicated the polymer to have a glass transition temperature of about 130° C. and a dissolution rate(in Shipley LDD-26W developer) of about 8200 A/s.

### EXAMPLES 29 THROUGH 36

Following the procedure according to Example 28, a series of terpolymers were prepared having different monomer incorporation and characteristics. The polymer compositions and their characteristics are summarized in Table 1.

TABLE 1

| | Polymer composition | | | | | | |
|---|---|---|---|---|---|---|---|
| | (mole %)* | | | Molecular weight | | T_{g} | DR |
| Example | X** | Y** | Z** | M_{w} | Mₙ | (° C.) | (Å/s) |
| 29 | 10.92 | 59.64 | 29.44 | 7810 | 5720 | 113 | 1.50 |
| 30 | 16.30 | 53.99 | 29.71 | 7720 | 5260 | 123 | 0.83 |
| 31 | 18.49 | 54.50 | 27.01 | 11900 | 8230 | 121 | |
| 32 | 21.10 | 49.33 | 29.57 | 13160 | 8770 | 127 | |
| 33 | 27.19 | 43.04 | 29.77 | 13570 | 8720 | 125 | |
| 34 | 29.67 | 37.07 | 33.26 | 13480 | 8450 | 125 | |
| 35 | 29.94 | 41.32 | 28.74 | 9330 | 6050 | 125 | 1.5 |
| 36 | 35.24 | 37.53 | 27.23 | 12360 | 7470 | 124 | |

*The polymer compositions determined using quantitative ¹³C and 19F NMR techniques.
**X: 4-Hydroxy-2,3,5,6-tetrafluorostyrene, Y: pentafluorostyrene, Z: t-butylmethacrylate.

### EXAMPLE 37

### Copolymer of 4-hydroxy-2,3,5,6-tetrafluorostyrene and Methyl 2-(trifluoromethyl)acrylate

One part of 4-hydroxy-2,3,5,6-tetrafluorostyrene and one part of methyl 2-(trifluoromethyl) acrylate are co-polymerized according to the procedure of Example 28 to produce a co-polymer in 57 percent yield with a composition consisting of 45 mole percent 4-hydroxy-2,3,5,6-tetrafluorostyrene and 55 mole percent methyl 2-(trifluoromethyl) acrylate as determined by quantitative NMR. GPC shows the polymer to have a Mw of about 3118 and a Mn of about 2099 Daltons.

### EXAMPLE 38

### Copolymer of 4-hydroxy-2,3,5,6-tetrafluorostyrene, and t-butyl 2-(trifluoromethyl)acrylate

Following the procedure according to Example 28 a copolymer of 4-hydroxy-2,3,5,6-tetrafluorostyrene and t-butyl 2-(trifluoromethyl) acrylate is prepared using equal monomer feed. The resulting copolymer was obtained in 31 percent yield has a composition, as determined by quantitative NMR, consists of 53 percent of 4-hydroxy-2,3,5,6-tetrafluorostyrene and 47 percent of t-butyl 2-(trifluoromethyl) acrylate. GPC analysis indicated the polymer to have a Mw of about 3294 and a Mn of about 2400 Daltons.

### EXAMPLE 39

### Terpolymer of 4-hydroxy-2,3,5,6-tetrafluorostyrene, pentafluorostyrene and t-butyl 2-(trifluoromethyl)acrylate

A monomer mixture comprising of 30 mole percent of 4-hydroxy-2,3,5,6-tetrafluorostyrene, 40 mole percent of pentafluorostyrene and 30 mole percent of t-butyl 2-(trifluoromethyl)acrylate is reacted according to the procedure of Example 26 to produce a terpolymer in 58 percent yield. The polymer composition as determined by quantitative NMR consists of 29 mole percent 4-hydroxy-2,3,5,6-tetrafluorostyrene, 43 mole percent pentafluorostyrene and 28 mole percent t-butyl 2-(trifluoromethyl)acrylate. GPC analysis indicated the polymer to have a Mw of about 5838 and a Mn of about 3976 Daltons.

### EXAMPLE 40

### Copolymer of 4-tert-butoxy-2,3,5,6-tetrafluorostyrene and Heptafluorobutyl Acrylate

4-tert-butoxy-2,3,5,6-tetrafluorostyrene (5.5 g, 20.14 mmol), heptafluorobutyl acrylate (1.28 g, 5.04 mmol) and 0.17 g, 1.04 mmol of AIBN in 9.2 mL of isopropanol are reacted at reflux for 16 h. Upon cooling, 3 mL of acetone is added and the solution slowly added to excess water to precipitate the polymer. The polymer was dried for 12 h at 75° C. under vacuum. The polymer had a Mw of about 32221 and a Mn of about 9664 Daltons as determined by GPC. The 157 nm absorbance of the polymer is 4.51/μm.

### EXAMPLE 41

### Copolymer of 4-tert-butoxy-2,3,5,6-tetrafluorostyrene and Heptafluorobutyl Methacrylate

4-tert-butoxy-2,3,5,6-tetrafluorostyrene (5.5 g, 20.14 mmol), heptafluorobutyl methacrylate (1.35 g, 5.04 mmol) and 0.17 g, 1.04 mmol of AIBN in 9.2 mL of isopropanol are reacted at reflux for 16 h. Upon cooling, 3 mL of acetone is added and the solution slowly added to excess water to precipitate the polymer. The polymer was dried for 12 h at 75° C. under vacuum. The polymer had a Mw of about 26087 and a Mn of about 8489 Daltons as determined by GPC. The 157 nm absorbance of the polymer is 4.31/μm.

The foregoing description of the invention is merely illustrative thereof, and it is understood that variations and modifications can be effected without departing from the spirit or scope of the invention as set forth in the following claims.

What is claimed is:

1. A method for forming a photoresist relief image, comprising:
(a) applying a photoresist composition on a substrate, the photoresist comprising a resin and a photoactive component, the resin comprising aromatic groups and electronegative groups;
(b) exposing the photoresist to activating radiation and developing the exposed photoresist layer.

2. The method of claim 1 wherein the photoresist is exposed with radiation having a wavelength of less than about 200 nm.

3. The method of claim 1 wherein the photoresist is exposed with radiation having a wavelength of less than about 170 nm.

4. The method of claim 1 wherein the photoresist is exposed with radiation having a wavelength of less than about 160 nm.

5. The method of claim 1 wherein the photoresist is exposed with radiation having a wavelength about 157 nm.

6. The method of claim 1 wherein the photoresist is exposed with radiation having a wavelength of less than about 300 nm.

7. The method of any one of claims 1 through 6 wherein the resin comprises phenolic units.

8. The method of any one of claims 1 through 7 wherein the resin is a novolak polymer.

9. The method of any one of claims 1 through 7 wherein the resin comprises polymerized vinylphenol units.

10. The method of any one of claims 1 through 9 wherein the resin comprises halogen, halogenated alkyl, nitro, nitrile, cyano, sulfinyl, or sulfonyl groups.

11. The method of any one of claims 1 through 9 wherein the resin comprises fluorine.

12. The method of any one of claims 1 through 11 wherein the polymer comprises acrylate units.

13. The method of any one of claims 1 through 12 wherein the photoresist is a chemically amplified positive resist.

14. The method of any one of claims 1 through 12 wherein the photoresist is a negative resist.

15. A method for forming a photoresist relief image, comprising:
(a) applying a photoresist composition on a substrate, the photoresist comprising one or more photoacid generators and a halogenated aromatic polymer;
(b) exposing the photoresist to radiation having a wavelength of about 170 nm or less and developing the exposed photoresist layer.

16. The method of claim 15 wherein the polymer is fluorinated.

17. The method of claim 15 or 16 wherein the polymer is a novolak.

18. The method of claim 15 or 16 wherein the polymer comprises polymerized vinylphenol units.

19. The method of any one of claims 15 through 18 wherein the photoresist is exposed to radiation having a wavelength of about 157 nm.

20. A photoresist composition comprising a photoactive component and a resin component that comprises a polymer comprising:
1) a polymer backbone comprising a plurality of carbon-carbon bond units,
2) a first electronegative group capable of withdrawing electrons from the polymer backbone; and optionally
3) a second electronegative group.

21. The photoresist of claim 20 wherein the polymer is a terpolymer.

22. The photoresist of claim 20 or 21 wherein the polymer comprises polymerized norbornene or ethylene units.

23. The photoresist of any one of claims 19 through 22 wherein the polymer comprises a first polymerized norbornene repeat unit, and a second polymerized norbornene repeat unit, the first and second norbornene units being different.

24. The photoresist of claim 23 wherein the first norbornene repeat comprises the first electronegative group, and the second norbornene repeat unit comprises the second electronegative group.

25. The photoresist of any one of claims 19 through 23 wherein the polymer comprises a first polymerized ethylene repeat unit, and a second polymerized ethylene repeat unit, the first and second ethylene units being different.

26. The photoresist of claim 25 wherein the first ethylene repeat unit comprises the first electronegative group, and the second ethylene repeat unit comprises the second electronegative group.

27. The photoresist of any one of claims 20 through 26 wherein the polymer further comprises an acid labile group.

28. The photoresist of claim 27 wherein the acid labile group is bound to a phenolic unit.

29. The photoresist of claim 27 wherein the acid labile group is bound to the polymer backbone.

30. The photoresist of claim 29 wherein the acid labile group is bound to a carbon atom substituted by the second electronegative group.

31. The photoresist of any one of claims 27 through 30 wherein the acid labile group is an ester, acetal, ketal, formal, or ether.

32. The photoresist of any one of claims 27 through 31 wherein the acid labile group comprises t-butyl, 2,2,-dimethyl-3,-methylpropyl, 1,1,2-trimethylpropyl, 1,1,2,2-tetramethylpropyl, tetrahydropyranyl, ethoxypropyl, ethyl-2-trimethylsilanyl, 2-oxa-bicylco[2.2.1] hept-6-yl (exoisomer), or 7-thia-bicyclo[2.2.1]hept-2-yl (endoisomer)

33. The photoresist of any one of claims 27 through 32 wherein the first electronegative group is one of halogen, nitrile or carboxyl.

34. The photoresist of claim 27 through 32 wherein the halogen is fluorine.

35. The photoresist of any one of claims 27 through 32 wherein the first electronegative group comprises fluorinated alkyl, fluorinated alkyl alcohol, perfluoroalkyl, or perfluoroalkylene.

36. The photoresist of any one of claims 27 through 32 wherein the first electronegative group comprises trifluoromethyl, difluoromethyl, monofluoromethyl, pentafluoroethyl, tetrafluoroethyl, trifluoroethyl, difluoroethyl, monofluoroethyl, difluorohydroxymethyl, monofluorohydroxymethyl, tetrafluorohydroxyethyl, trifluorohydroxyethyl, difluorohydroxyethyl, monofluorohydroxyethyl, hexafluorohydroxyisopropyl, pentafluorohydroxyisopropyl, tetrafluorohydroxyisopropyl, trifluorohydroxyisopropyl, difluorohydroxyisopropyl, monofluorohydroxy-tert-butyl, difluorohydroxy-tert-butyl, trifluorohydroxy-tert-butyl, tetrafluorohydroxy-tert-butyl, pentafluorohydroxy-tert-butyl, hexafluorohydroxy-tert-butyl, septafluorohydroxy-t-butyl, octafluorohydroxy-t-butyl, difluorooxymethyl, monofluorooxymethyl, tetrafluorooxyethyl, trifluorooxyethyl, difluorooxyethyl, monofluorooxyethyl, hexafluorooxyisopropyl, pentafluorooxyisopropyl, tetrafluorooxyisopropyl, trifluorooxyisopropyl, difluorooxyisopropyl, or monofluorooxyisopropyl group.

36. The photoresist of claim 35 wherein the acid labile group is bound to the carbon atom attached to the acrylonitrile group.

37. The photoresist of any one of claims 20 through 36 wherein the polymer comprises units of the following formula: 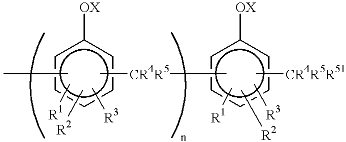
each R¹, R² and R³ may be the same or different and may be hydrogen or a non-hydrogen substituent provided at least one of R¹, R² and R³ is a halogenated substituent;
each R⁴, R⁵ and R^{5′} may be the same or different and may be hydrogen or a non-hydrogen-substituent;
X is hydrogen or non-hydrogen substituent particularly to form an acid labile group with the depicted oxygen, such as to form an ester, ether, acetal or the like;
n is greater than zero and is the mole percent of the depicted polymer unit.

38. A positive chemically-amplified photoresist composition comprising one or more photoacid generator compounds and a fluorinated novolak resin or a fluorinated resin comprising polymerized vinyl phenol units.

39. The photoresist of claim 38 wherein the polymer is a novolak.

40. The photoresist of claim 38 wherein the polymer comprises polymerized vinylphenol units.

41. A photoresist composition comprising a photoactive component and a resin binder comprising a polymer that comprises repeat units of:
1) a group comprising a polymer backbone comprising a first phenolic ring substituted with hydrogen or at least one first electronegative group, the backbone further comprising at least one methylene unit optionally substituted with at least one second electronegative group,
2) a group comprising a second phenolic ring substituted with hydrogen or at least one third electronegative group,
3) a group comprising a third phenolic ring substituted with hydrogen or at least one fourth electronegative group,
wherein,
each of the electronegative groups is the same or different, and each of the phenolic rings is the same or different.

42. The photoresist composition of claim 41 wherein the group comprising the second phenolic ring feature comprises a methylene unit optionally substituted with a fifth electronegative group the same or different from the first, second, third or fourth electronegative groups.

43. The photoresist of claim 41 or 42 wherein the second phenolic ring feature comprises a further electronegative group.

44. The photoresist of any one claims 41 through 43 wherein the third phenolic ring feature comprises a further electronegative group.

45. The photoresist composition of any one claims 41 through 45 wherein the polymer comprises a polymerized cresol formaldehyde (novolak) unit.

46. The photoresist composition of any one of claims 41 through 46 wherein the polymer comprises a trifluoromethylphenol unit.

47. The photoresist composition of any one of claims 41 through 46 wherein the polymer comprises a polymerized optionally substituted styrene unit.

48. The photoresist of any one of claim 42 through 48 wherein the polymer comprises a first substituted novolak repeat unit, a substituted second novolak repeat unit and a third substituted novolak repeat unit, each of the first, second and third substituted novolak units being different.

49. A photoresist comprising a polymer, the polymer comprising units of the following formula: 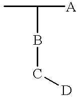
wherein A is a polymer backbone, B is a ballast moiety, C is an acidic moiety, and D is a chemically cleavable group wherein at least one of A, B, C or D comprises at least one electronegative group.

50. A photoresist of claim 49 wherein the polymer comprises novolak units.

51. A photoresist of claim 49 wherein the polymer comprises polymerized vinylphenol units.

52. A photoresist of claim 49 wherein the polymer is a novolak or a poly(vinylphenol).

53. The photoresist of any one of claims 20 through 52 wherein the polymer comprises an acid-labile repeat unit separate from a phenolic unit.

54. The photoresist of any one of claims 20 through 53 wherein the polymer is a terpolymer, tetrapolymer, or pentapolymer.

55. The photoresist of any one of claims 20 through 54 wherein the photoresist comprises at least two distinct polymers.

56. The photoresist of claim 55 wherein one of the two distinct polymers comprises aromatic units and the other polymer is substantially free of aromatic groups.

57. A method of forming a photoresist relief image, comprising:
(a) applying a coating layer of a photoresist of any one of claims 20 through 56 on a substrate; and
(b) exposing and developing the photoresist layer to yield a relief image.

58. The method of claim 57 wherein the photoresist layer is exposed with radiation having a wavelength of less than about 200 nm.

59. The method of claim 57 wherein the photoresist layer is exposed with radiation having a wavelength of less than about 170 nm.

60. The method of claim 57 wherein the photoresist layer is exposed with radiation having a wavelength of about 157 nm.

61. The method of claim 57 wherein the photoresist layer is exposed with radiation having a wavelength of less than about 300 nm.

62. An article of manufacture comprising a substrate having thereon a photoresist of any one of claims 20 through 56.

63. An article of claim 62 wherein the substrate is a microelectronic wafer or an optical-electronic substrate.

64. A method for producing a halogenated phenolic polymer comprising oxidizing a polymer and then halogenating the polymer.

65. A method of claim 64 wherein the polymer is not halogenated prior to oxidation.

66. A method of claim 64 or 65 wherein the polymer is fluorinated.

67. A method of any one of claims 64 through 66 wherein the polymer is a novolak polymer.

68. A method of any one of claims 64 through 66 wherein the polymer comprises polymerized vinylphenol units.

69. A photoresist composition comprising one or more photoacid generator compounds and a halogenated polymer obtainable by steps comprising oxidizing a polymer and then halogenating the polymer.

70. A photoresist of claim 69 wherein the polymer is not halogenated prior to oxidation.

71. A photoresist of claim 69 or 70 wherein the polymer is fluorinated.

72. A photoresist of any one of claims 69 through 71 wherein the polymer is a novolak polymer.

73. A photoresist of any one of claims 69 through 71 wherein the polymer comprises polymerized vinylphenol units.
